(19) United States
(12) Patent Application Publication
(10) Pub. No.: US 2026/0360656 A1
(43) Pub. Date: Nov. 12, 2026

(54) METHOD FOR PRODUCING A MICRO-OPTICAL UNIT FOR A MULTIPLE PARTICLE BEAM SYSTEM, MICRO-OPTICAL UNIT AND MULTIPLE PARTICLE BEAM SYSTEM

(71) Applicant: Carl Zeiss MultiSEM GmbH, Oberkochen (DE)

(72) Inventors: Benedikt TRATZMILLER, Stuttgart (DE); Christian VEIT, Leinfelden-Echterdingen (DE); Michael SCHALL, Essingen (DE); Marcus KAESTNER, Syrgenstein-Staufen (DE); Alexander HUEBEL, Schorndorf (DE); Dirk ZEIDLER, Oberkochen (DE); Thomas SCHMID, Aalen (DE)

(21) Appl. No.: 19/683,708

(22) Filed: May 20, 2026

Related U.S. Application Data
(63) Continuation of application No. PCT/EP2024/025330, filed on Nov. 29, 2024.

(30) Foreign Application Priority Data
Nov. 30, 2023 (DE) 10 2023 133 567.7

(51) Int. Cl. H01J 37/09; H01J 37/14; H01J 37/28

(52) U.S. Cl. CPC H01J 37/09; H01J 37/14; H01J 37/28; H01J 2237/0453; H01J 2237/2801

(57) ABSTRACT

A method comprises: (a) providing a first plate of the micro-optical unit, which is electrically conductive; (b) providing a second plate of the micro-optical unit, which is electrically conductive; (c) creating a plate stack, which comprises the step of stacking the first plate of the micro-optical unit and the second plate of the micro-optical unit on top of each other, wherein the first plate of the micro-optical unit and the second plate of the micro-optical unit are fixed in the plate stack relative to each other and electrically insulated from each other; and (d) piercing the entire created plate stack having at least the first plate and the second plate of the micro-optical unit, thereby creating both a first plurality of apertures in the first plate of the micro-optical unit and a second plurality of apertures in the second plate of the micro-optical unit.

### CROSS-REFERENCE TO RELATED APPLICATIONS

The present application is a continuation of, and claims benefit under 35 USC 120 to, international application No. PCT/EP2024/025330, filed Nov. 29, 2024, which claims benefit under 35 USC 119 of German Application No. 10 2023 133 567.7, filed Nov. 30, 2023. The entire disclosure of each of these applications is incorporated by reference herein.

### FIELD

The disclosure relates to multiple particle beam systems in general and, for example, to multi-beam particle microscopes operating with a plurality of individual charged particle beams. The disclosure also relates to a method for producing a micro-optical unit for a multiple particle beam system, to a micro-optical unit and to a multiple particle beam system.

### BACKGROUND

With the ongoing development of ever smaller and ever more complex microstructures such as semiconductor components, it is generally desirable to further develop and optimize planar production techniques and inspection systems for producing and inspecting small dimensions of the microstructures. For instance, the development and production of the semiconductor components involve monitoring of the design of test wafers, and the planar production techniques can involve process optimization for reliable production with high throughput. Moreover, there have been recent demands for an analysis of semiconductor wafers for reverse engineering and for a customized, individual configuration of semiconductor components. Therefore, there is a desire for an inspection mechanism which can be used with high throughput to examine the microstructures on wafers with high accuracy.

Typical silicon wafers used in the production of semiconductor components have diameters of up to 300 mm. Each wafer is divided into 30 to 60 repeating regions ("dies") with a size of up to 800 mm². A semiconductor apparatus comprises multiple semiconductor structures, which are produced in layers on a surface of the wafer by planar integration techniques. Semiconductor wafers typically have a plane surface on account of the production processes. The structure dimension of the integrated semiconductor structures in this case extends from a few µm to the critical dimensions (CD) of a few nanometres, with the structure dimensions becoming even smaller in the near future; the expectation is that in future the structure dimensions or critical dimensions (CD) will correspond to the 3 nm, 2 nm or even smaller process nodes of the International Technology Roadmap for Semiconductors (ITRS). In the case of the aforementioned small structure dimensions, it is generally desirable to detect defects of the order of the critical dimensions relatively quickly over a relatively large area. For multiple applications, the desired accuracy of a measurement provided by inspection equipment is even higher, for example by a factor of two or one order of magnitude. For instance, it can be desirable to measure a width of a semiconductor feature with an accuracy of better than 1 nm, for example 0.3 nm or even less, and a relative position of semiconductor structures with an overlay accuracy of better than 1 nm, for example 0.3 nm or even less.

The MSEM, a multi-beam scanning electron microscope, is a relatively new development in the field of charged particle systems (“charged particle microscopes”, CPMs). For instance, a multi-beam scanning electron microscope is disclosed in US 7 244 949 B2 and in US 2019/0355544 A1. In the case of a multi-beam electron microscope or MSEM, a sample is irradiated simultaneously by a plurality of individual electron beams arranged in a field or raster. For instance, 4 to 10,000 individual electron beams can be provided as primary radiation, with each individual electron beam being separated from an adjacent individual electron beam by a pitch of 1 to 200 micrometres. For example, an MSEM has approximately 100 separate individual electron beams (“beamlets”), which for instance are arranged in a hexagonal raster, with the individual electron beams being separated by a pitch of approximately 10 µm. The plurality of individual charged particle beams (primary beams) are focused on a surface of a sample to be examined by way of a common objective lens. For example, the sample can be a semiconductor wafer which is secured to a wafer holder mounted on a movable stage. When the wafer surface is illuminated by the primary individual charged particle beams, interaction products, for example secondary electrons or backscattered electrons, emanate from the surface of the wafer. Their start points typically correspond to those locations on the sample on which the plurality of individual primary particle beams are focused in each case. The amount and the energy of the interaction products generally depend on the material composition and the topography of the wafer surface. The interaction products usually form multiple secondary individual particle beams (secondary beams), which are collected by the common objective lens and, after passing through a projection imaging system of the multi-beam inspection system, are incident on a detector arranged in a detection plane. The detector can comprise multiple detection regions, each of which comprises several detection pixels, and the detector captures an intensity distribution for each of the secondary individual particle beams. An image field of 100 µm × 100 µm, for example, can be obtained in the process.

Certain known multi-beam electron microscopes comprise a sequence of electrostatic and magnetic elements. At least some of the electrostatic and magnetic elements can be set in order to adapt the focus position and the stigmation of the plurality of individual charged particle beams. The systems with charged particles moreover can comprise at least one crossover plane of the primary or the secondary individual charged particle beams. Moreover, the systems can comprise detection systems in order to facilitate setting. The beam particle microscopes can comprise at least one beam deflector (“deflection scanner”) for collective scanning of a region of the sample surface via the plurality of primary individual particle beams in order to obtain an image field of the sample surface.

What is known as a beam splitter (or alternatively beam separator or beam divider) is often used to separate the particle-optical beam path of the primary beams from the particle-optical beam path of the secondary beams. In this case, separation can be implemented via special arrangements of magnetic fields and/or electrostatic fields, for example via a Wien filter.

In the case of multiple particle beam systems, a distinction is made in general between systems that work with a single column and systems that work with multiple columns. In systems with a single column, the individual particle beams at least in part pass through the same particle-optical unit or through one or more global particle lenses. In addition, in a single column, the individual particle beams are relatively close to one another. Despite the partially global particle-optical elements, there can be a desire for individual controllability and/or formability of the individual particle beams even in the case of single columns, in order to correct imaging aberrations such as image field curvature, field astigmatism and other aberrations. A so-called micro-optical unit can be used for this individual influencing and/or shaping of the individual particle beams. The micro-optical unit is often also referred to as a multi-beam particle generator for creating and shaping a plurality of individual particle beams. The multi-beam particle generator or the micro-optical unit can comprise a sequence of several multi-aperture plates, which can be used for active beam shaping or of which at least one multi-aperture plate can be used for active beam shaping. For example, electrodes that can be controlled collectively or on an individual basis can be provided to this end in the region of the apertures. For example, these can be ring electrodes or multi-pole electrodes. According to another example, a multi-aperture plate can have a monolithic embodiment, with a voltage applied to the multi-aperture plate overall, i.e. the monolithic multi-aperture plate then is at a certain potential, and so its openings can create a lens effect in interaction with other particle-optical elements. Other configurations of a multi-aperture plate for active beam shaping are also possible.

For good individual particle beam shaping/individual particle beam influencing, it is generally desirable for the apertures passed by an individual particle beam to be exactly aligned with one another. For example, it can be desirable for the centres of the apertures to have to lie exactly on top of one another. Moreover, the apertures in certain known multi-aperture plates are relatively small, e.g. aperture diameters are each less than 100 µm, e.g. only 90 µm or less. These two conditions – small size of the aperture diameters and precise alignment of the apertures/electrodes, including control – can be met by using MEMS techniques for producing a micro-optical unit. In other words, similar processes to those also used in semiconductor production can be used for the production of a micro-optical unit or its multi-aperture plates.

The applications of semiconductor components are rendered possible, for example, by combining regions of different doping or by the influence of insulating separation layers. In order to meet these desired properties, various layers are applied successively to a base substrate in the form of a disc, the so-called wafer, during the production of semiconductor components (the so-called planar process). For example, silicon is used as the base substrate, while e.g. silicon oxide is used as the insulating layer. The applied layers can then each be structured via lithographic methods. Thus, integrated circuits with conductor tracks, i.e. semiconductor chips, can be created – or simply even micro-optical units with multi-aperture plates for multiple particle beam systems.

Even though the production of micro-optical units via MEMS techniques is very precise, there nevertheless can be undesirable with this type of production. The development time for the production of a micro-optical unit is relatively long and often ranges from half a year to three quarters of a year. Changes in the production process are possible only with difficulty or only with considerable amounts of time. And overall, there are only a few semiconductor manufacturers, the process control of semiconductor manufacturing can be challenging, and relatively expensive equipment is typically used for semiconductor manufacturing.

### SUMMARY

The disclosure seeks to provide an improved method for producing a micro-optical unit for a multiple particle beam system. For example, it is desirable for the method to be faster than known methods, optionally without sacrificing quality in the micro-optical unit or worsening an achievable resolution in multiple particle beam systems. Optionally, the method should be easy and cost-effective to implement.

The present disclosure provides the insights:
(1) It transpired that the material used for a micro-optical unit, silicon, can cause relatively serious issues. For example, unwanted surface potentials can occur, and the conductivity of the silicon can change over time. Both have an unwanted influence on the individual charged particle beams when passing through the micro-optical unit and hence on the beam quality and, as a result, in turn on the resolution achievable via a multiple particle beam system during its operation.
(2) In addition, it surprisingly transpired that the desire/the trend towards further miniaturization of the micro-optical unit for the purpose of improving resolution is not always correct or not always necessary. Instead, real desirable features can be identified in producing the micro-optical unit with slightly larger dimensions, for example with larger apertures and/or thicker multi-aperture plates. Desirable features can be offered, for example, due to reduced parasitic effects such as reduced beam deflections in the event of a comparable desired electron-optical effect and due to higher voltages that can be applied to the multi-aperture plates of the micro-optical unit. For example, the latter is of particular interest for more and more individual particle beams and for ever larger image fields in the case of micro-optical units.

A concept of the disclosure is to use other production processes instead of MEMS techniques, for example to use those production processes that can be used in metal processing. The fact that such processes for metal processing tend to be used only to create slightly larger structures is not necessarily an undesirable feature in this context. Instead, metal processing processes can offer the feature that silicon no longer has to be used as a material in a quasi-compulsory manner. For example, a method according to the disclosure can also be used to produce micro-optical units having one or more multi-aperture plates made of metal. In addition, the issue of exactly aligning the multi-aperture plates to one another can also be solved in the event of a skilful procedure, to be precise independently of their material or light-optical or IR transparency. In that case, the multi-aperture plates can be automatically or process-inherently correctly aligned with one another.

According to a first aspect of the disclosure, the disclosure relates to a method for producing a micro-optical unit for a multiple particle beam system, said method including the following steps:
(a) providing a first plate of the micro-optical unit, which is electrically conductive;
(b) providing a second plate of the micro-optical unit, which is electrically conductive;
(c) creating a plate stack, which comprises the step of stacking the first plate of the micro-optical unit and the second plate of the micro-optical unit on top of each other, wherein the first plate of the micro-optical unit and the second plate of the micro-optical unit are fixed in the plate stack relative to each other and are electrically isolated from each other; and (d) piercing the entire created plate stack having at least the first plate and the second plate of the micro-optical unit, and thereby creating both a first plurality of apertures in the first plate of the micro-optical unit and a second plurality of apertures in the second plate of the micro-optical unit.

Like in the introductory part of the description as well, the term micro-optical unit is understood to mean a sequence of several multi-aperture plates, of which at least one multi-aperture plate is used during operation for the active beam shaping of the plurality of individual particle beams in the multiple particle beam system. Each of the apertures can be passed by exactly one individual particle beam.

Such a method does not initially refer to a multi-aperture plate, but to a first plate of the micro-optical unit and a second plate of the micro-optical unit. This is due to the fact that the apertures in the first plate and in the second plate are formed during the production method.

The first plate of the micro-optical unit can be electrically conductive. Electrical conductivity can extend to the entire first plate of the micro-optical unit or only to portions of the first plate. The same can apply to the second plate of the micro-optical unit. The property of electrical conductivity contributes to or is even desirable for the ability to use many methods known from metal processing in the production of the micro-optical unit for a multiple particle beam system. This will be explained in detail hereinbelow.

The creation of the plate stack can comprise the step of stacking the first plate of the micro-optical unit and the second plate of the micro-optical unit on top of each other, wherein the first plate of the micro-optical unit and the second plate of the micro-optical unit are fixed in the plate stack relative to each other and electrically isolated from each other. Fixation and electrical insulation can be realized simultaneously and/or by the same approach, but it is also possible that different approaches are used for fixation and electrical insulation. For example, electrically insulating spacers can be used, or a complete electrically insulating plate can be provided.

The plate stack can comprise at least a first plate of the micro-optical unit and a second plate of the micro-optical unit. However, the plate stack can also comprise further plates of the micro-optical unit. In any case, method step (d) can see implementation of the following: piercing of the entire created plate stack having at least the first plate and the second plate of the micro-optical unit, and thereby creating both a first plurality of apertures in the first plate of the micro-optical unit and a second plurality of apertures in the second plate of the micro-optical unit. Apertures that should be passed by the same individual particle beam during the operation of the micro-optical unit or the multiple particle beam system can thus be created in the same method step or during the same piercing event. Thus, in the event of correspondingly accurate implementation of the piercing via a drilling mechanism, mutually assigned apertures in the first plate of the micro-optical unit and in the second plate of the micro-optical unit and optionally in one or more further plates of the micro-optical unit can be automatically correctly aligned with one another.

According to an embodiment of the disclosure, the first plate of the micro-optical unit and/or the second plate of the micro-optical unit is metallic. For example, the metal can be copper, silver, iron, aluminium, tungsten, gold, brass, platinum, stainless steel or else any other metal or a metal alloy or combinations of the aforementioned materials. The metal plate itself can also comprise a surface finish, for example a gold plating. In an alternative, it is also possible that the first plate of the micro-optical unit and/or the second plate of the micro-optical unit comprises or consists of a semiconductor material. For example, this semiconductor material can comprise silicon.

According to an embodiment of the disclosure, the plate stack further comprises at least one further plate and thus at least a third plate of the micro-optical unit, which is electrically conductive. In this case, the third plate of the micro-optical unit is fixed relative to the first plate of the micro-optical unit and the second plate of the micro-optical unit and is electrically isolated therefrom in each case. The third plate of the micro-optical unit can also be pierced while method step (d) is carried out, and so a third plurality of apertures in the third plate of the micro-optical unit are thereby generated. This third plurality of apertures thus can also be process-inherently correctly aligned to the other apertures of the first plate and the second plate.

According to an embodiment of the disclosure, the third plate of the micro-optical unit can comprise or consist of a metal. The same applies to any additional plates that can be present. In general, it is possible that all plates of the micro-optical unit comprise or consist of the same material and of the same metal for example. However, this is not necessarily the case.

According to an embodiment of the disclosure, the first plate and/or the second plate and/or the third plate and/or a further plate of the micro-optical unit is magnetically conductive. Additionally, the following relation can apply (in each case) to a relative permeability µᵣ of the material of the plate: µᵣ ≥ 1000, such as µᵣ ≥ 10 000 or µᵣ ≥ 15 000.

A magnetic conductivity of one of the plates, of several of the plates or even of all of the plates can help enable extended areas of application or possible uses of a micro-optical unit. For example, a plate or a sequence of plates in the micro-optical unit is used to set a focusing. Magnetically conductive plates and, for example, a final multi-aperture plate as regards the particle-optical beam path during the operation of the micro-optical unit can also fulfil the function of a multi-deflector in combination with a magnetic lens arranged just downstream. For such an application, the final multi-aperture plate is arranged, or can be arranged, within the magnetic field of the downstream magnetic lens. A specific configuration of such a multi-deflector will be discussed in further detail below.

There are various known magnetically conductive materials with a relative permeability of µᵣ ≥ 1000. These include inter alia standard soft-magnetic materials such as pure iron (e.g. Vacofer^{®}), nickel-iron alloys with an approximately 75 % nickel content such as Mu Metal, Permalloy or Supermalloy, nickel-iron alloys with an approximately 50 % nickel content such as e.g. Permenorm^{®}, cobalt-iron alloys with an approximately 50 % cobalt content such as e.g. Vacoflux^{®}, or silicon-iron alloys with an approximately 3 % silicon content such as e.g. Trafoperm^{®}. These materials are also commercially available as thin membranes, for example with a thickness of 25 µm, 50 µm, 100 µm or 250 µm. On account of the low thickness, plates made of such materials can be suitable in general for a method according to the disclosure for producing a micro-optical unit for a multiple particle beam system.

According to an embodiment of the disclosure, the plate stack is pierced in step (d) via laser drilling. Laser drilling is a non-machining thermal separation method. There are various types of laser drilling techniques, such as single pulse drilling, percussion drilling, trepanning and helical drilling. Single pulse drilling is the fastest; it is "shot" through the material via a single pulse. Percussion drilling involves placing multiple pulses at the same point to laser a hole through the material. Trepanning refers to the hole being cut out by travelling along the drilling contour after the through hole has been created. Helical drilling can involve special optics. What holds true at a basic level is that the precision of the drilled hole and the smoothness of the drilled hole walls generally depend on the material pierced and the type of laser radiation. For example, copper absorbs green and blue radiation relatively well, but common infrared not so well. Nowadays, laser drilling methods can be relatively fast and also relatively efficient. For example, it is possible to drill 200 holes per second in 1 mm thick sheet titanium using single pulse micro-drilling. For example, a focus diameter of the utilized laser is 12 µm, and the resultant drilled hole has a diameter of only just 80 µm. An aperture diameter of 80 µm already corresponds to the dimensions of apertures known to be used when these are created using MEMS techniques. Thus, laser drilling can be used to produce very small apertures – if desired – as well as far larger apertures – if desirable using a technique other laser drilling techniques. In addition, the methods are very fast. Moreover, as a production method, laser drilling can offer the feature that the material to be pierced does not necessarily have to be a metal or even be conductive. Insulators can also be pierced by laser drilling. In laser drilling, even plate stacks with a sequence of electrically conductive and electrically insulating plates can therefore be pierced at once or via the same laser pulse or via the same plurality of laser pulses.

According to an embodiment of the disclosure, the plate stack is pierced in step (d) via micro-EDM. Micro-EDM or micro-spark erosion is a form of EDM (electrical discharge machining) and can be described as a combination of drill erosion and sinker erosion techniques. This technique, which is based on spark erosion as machining method, can be relatively well suited to bringing electrically conductive materials of different hardnesses into the right shape with high speed and precision.

EDM is a contactless method that allows material to be removed over very short lengths without creating mechanical stresses in the material as a result. The material is shaped by highly localized melting and evaporation due to electrical discharges between an electrode and the material to be processed. The discharges, which form tiny plasma channels at temperatures of up to 10 000° C, locally melt very small quantities of the material. If the current flow is interrupted, the created plasma collapses, and the resulting vacuum pulls the molten material out into the surrounding dielectric medium. In order for discharges to be able to occur, the material has sufficient electrical conductivity, while material hardness does not matter. Therefore, all metals and many semiconductors can be suitable for EDM and also for micro-EDM as a matter of principle.

Micro-EDM is a special form of the EDM in which the workpieces generally can have features of only approximately 10 µm. These relatively small features are obtained using electrodes that are also very small. Thus, micro-EDM can also be used to easily obtain the orders of magnitude of apertures that are already used for micro-optical units. Moreover, the micro-EDM process can be significantly faster than planar integration techniques.

According to an embodiment of the disclosure, the plate stack is pierced in step (d) via mechanical high-speed micro-drilling. For example, solid carbide micro-drills can be used for this purpose. In this way, drilled hole diameters of a few millimetres can be realized, as can drilled hole diameters of only 30 µm or even only 10 µm.

According to an embodiment of the disclosure, the plate stack is pierced in step (d) via vibration drilling or via ultrasonic drilling. The principle of vibration drilling lies in the creation of axial vibrations or oscillations in addition to the feed movement of the drill, and so the drill chips can break up and then be easily removed from the cutting zone. A distinction is made between self-sustaining vibration systems and forced vibration systems. In vibration drilling with Eigen vibration, the Eigen frequency of the tool is used to make it vibrate naturally during cutting. The vibrations can be maintained by a mass-spring system in the tool holder itself. Another option lies in the use of a piezoelectric system for creating and controlling vibrations. These systems can allow high vibration frequencies (up to 2 kHz) with small dimensions (a few µm) and are particularly suitable for drilling small holes.

Ultrasonic drilling uses oscillations in the ultrasonic range to create a drilled hole. This is a machining material processing method that does not operate on the basis of rotational machining. It can be used for hard and brittle materials for example. The drilling tool is set to vibrate in the feed direction by ultrasonic waves created in an ultrasonic transducer and also stimulates the grains of a supplied abrasive suspension to vibrate. The workpiece is removed in micro-districts during a short fraction of the oscillation period. It is also possible to supplement conventional drilling with the additional use of ultrasound in order to improve operating parameters.

According to an embodiment of the disclosure, the plate stack is pierced in step (d) using a focused ion beam (FIB). When high-energy ions strike a sample, they can sputter atoms out of the surface. On account of the sputtering capability, a focused ion beam can be used as a tool for micro- and nano-processing, and materials in the micro- and nano-range can be modified or processed. For example, gallium ions can be used as focused ions, but other ions can be used as well. The use of focused ion beams can even allow milling of features in the range of 10 to 15 nm. The milling of features in the micrometre range can be completely and comprehensively possible. One issue with the application of a focused ion beam lies only in its relatively shallow depth of focus. Therefore, it can be difficult to pierce thick plates or thick plate stacks in one go. However, even this case has solutions, for example the splitting of a plate stack into several sub-stacks and then the respective piercing of the sub-stacks using the FIB, especially at lens transitions, where an exact alignment of the apertures to one another of different plates is relevant. The sub-stacks can then be assembled into an overall stack.

In the above-described drilling methods, the material removed via piercing is to be removed from the plate stack. According to an embodiment of the disclosure, flushing holes can therefore be provided or have been provided in the plates in the plate stack, the said flushing holes having a greater diameter than the apertures in the first plate of the micro-optical unit and in the second plate of the micro-optical unit. These flushing holes can be created by the same methods or by other methods vis-à-vis the apertures in the first plate of the micro-optical unit and in the second plate of the micro-optical unit; the method itself is not decisive here. Instead, it is relevant that the diameter of the flushing holes is chosen in such a way that, in a flushing operation in a process chamber following the piercing of the plate stack, the removed material can be removed or flushed out through these flushing holes via a flushing operation. For example, a liquid can be used as a flushing agent, especially in a metal drilling process. However, it is also possible to use a gas as a flushing agent, for example after piercing via laser drilling or after using a focused ion beam.

Flushing holes also can allow the subsequent removal or flushing-out from the micro-optical unit of any auxiliary materials possibly used in the production of the plate stack/the micro-optical unit. For example, it is possible to introduce a liquid between the plates of the plate stack in advance of a mechanical drilling process, then cool the said liquid down to solidification and then perform the piercing of the plate stack. As a result, forces acting during piercing can also be absorbed by the solidified liquid. After piercing, the plate stack can be heated again, the solidified liquid/the solid is liquefied again and can then be flushed out through the flushing holes.

According to an embodiment of the disclosure, the method furthermore includes the following step: after piercing according to step d), flushing the plate stack and removing drilling material through flushing holes in the first plate of the micro-optical unit and in the second plate of the micro-optical unit, wherein the following relation applies to a diameter S of the flushing holes in relation to the diameter A of the apertures in the first plate of the micro-optical unit and in the second plate of the micro-optical unit: S ≥ 10A, such as S ≥ 100A.

According to an embodiment of the disclosure, the method moreover includes the following steps:
in advance of piercing according to step d)
filling an intermediate space between the first plate of the micro-optical unit and the second plate of the micro-optical unit with a flushing agent, and
cooling the flushing agent and thus solidifying the flushing agent; and after piercing according to step d)
heating the flushing agent and thereby liquefying the flushing agent; and
removing the flushing agent from the intermediate space.

The flushing holes described above can serve for the filling with the flushing agent and for the removal of the flushing agent.

According to an embodiment of the disclosure, the method furthermore comprises the following step:
after piercing according to step d)
annealing the plate stack.

Annealing the plate stack can serve to restore the soft-magnetic properties or the high magnetic conductivity of a magnetic plate. Voltages or vibrations that may arise in the method according to the disclosure for producing a micro-optical unit for a multiple particle beam system could otherwise reduce the magnetic conductivity to such an extent that desired effects such as multi-deflection of individual particle beams can no longer be realized via the plate. If a plate stack is annealed at a high temperature, care is also to be taken to ensure that electrical insulations between individual plates in the plate stack can also withstand the high temperatures of the annealing process. In general, this can be ensured by an appropriate material selection for the insulators.

According to an embodiment of the disclosure, at least one of the plates in the plate stack comprises an insulating material as base material, for example a ceramic as base material, and the method further includes the following steps, which are carried out temporally in advance of method steps (a) to (d):
(e) creating a plurality of coarse apertures in the at least one plate having the insulating material as base material; and
(f) metallizing the coarse apertures; wherein the subsequent implementation of method step (d) sees piercing of the metallized coarse apertures and hence formation of the plurality of apertures.

Thus, in this exemplary embodiment, it is not the entire plate of the plate stack that is conductive, but only a portion thereof, specifically the regions that are metallized around the coarse apertures. This can be sufficient to be able to carry out all material-processing methods that involve conductivity of the material to be pierced. Naturally, the diameter of the coarse apertures is larger than the diameter of the apertures of the completed multi-aperture plates. By contrast, the metallized coarse apertures are smaller in terms of diameter than the completed aperture diameters in the multi-aperture plate.

According to an embodiment of the disclosure, the coarse apertures are metallized via sputtering and/or via electroplating.

According to an embodiment of the disclosure, the plurality of apertures in the plates in the plate stack are created simultaneously in method step (d). To this end, a plurality of drilling mechanisms can be used at the same time. For example, these can be multiple laser pulses during laser drilling or else a plurality of electrodes that are fixedly oriented relative to one another (so-called "Manhattan electrodes") in the micro-EDM method. This type of simultaneous production of drilled holes is very fast.

According to an alternative embodiment of the disclosure, the plurality of apertures in the plates in the plate stack are created successively in method step (d). This means that the entire plate stack is first fully pierced at a first point, then fully pierced at a second point and so on. In this embodiment variant, the procedure of the applied drilling method can be comparatively simple.

According to an embodiment of the disclosure, the plurality of apertures each have a diameter A, wherein the following applies: 40 µm ≤ A ≤ 400 µm, such as 80 µm ≤ A ≤ 400 µm, or 110 µm ≤ A ≤ 400 µm. For circular apertures, the diameter naturally corresponds to twice the radius. In the case of differently shaped apertures, for example elliptical apertures, the smallest possible distance between hole walls from one another is defined as diameter A. In the case of ellipses, this then thus corresponds to twice the semi-minor axis. In the case of stepped apertures, which for example can be created via stepped electrodes or via several drilling steps (e.g. first piercing of a plate using a small drilling mechanism, then partially drilling open using a larger drilling mechanism), the diameter A refers to the minimum diameter.

According to an embodiment of the disclosure, the shape of the apertures in the plates in the plate stack has a round, elliptical, n-fold or irregular shape. In this respect, the method according to the disclosure can be very flexible.

According to an embodiment of the disclosure, the centres of adjacent apertures in the plates in the plate stack have a distance B, to which the following applies: 70 µm ≤ B ≤ 400 µm, such as 90 µm ≤ B ≤ 400 µm, or 120 µm ≤ B ≤ 400 µm.

According to an embodiment of the disclosure, the following applies to a thickness C of a plate in the plate stack: 20 µm ≤ C ≤ 500 µm, such as 150 µm ≤ C ≤ 500 µm, or 250 µm ≤ C ≤ 500 µm.

According to an embodiment of the disclosure, the following applies to a plate distance D between directly adjacent plates in the plate stack: 1 µm ≤ D ≤ 100 µm, such as 20 µm ≤ D ≤ 100 µm, or 40 µm ≤ D ≤ 100 µm.

According to an embodiment of the disclosure, the following applies to an overall height H of the plate stack: 50 µm ≤ H ≤ 1000 µm, such as 300 µm ≤ H ≤ 1000 µm, or 500 µm ≤ H ≤ 1000 µm.

A method according to the disclosure thus also enables piercing of relatively thick plates and relatively far apart plates, specifically via a relatively fast and relatively precise method. For example in the case of larger dimensions, the production process using the known planar integration techniques can be relatively slow.

According to an embodiment of the disclosure, the micro-optical unit comprises at least a second or further plate stack. In this case, the second or further plate stack of the micro-optical unit can be created via method steps (a) to (d). However, it is also possible that the second or further plate stack of the micro-optical unit is created or has been created via a planar process and/or lithographic methods. In general, other production methods are also possible.

According to an embodiment of the disclosure, the first plate stack and the second or further plate stack are aligned with each other in a method step (g). A high degree of precision is typically involved should several plate stacks be aligned to one another. However, this retrospective alignment of plate stacks or apertures contained therein can be naturally less accurate than the process-inherent positioning of the apertures within a plate stack if related apertures were created exactly via the same method step. Therefore, it can be expedient to provide the alignment of plate stacks to each other at those transitions between different plate stacks that have greater immunity to misalignments from an electron-optical point of view. In this context, reference is made once again to statements made in connection with focused ion beam drilling. In general, the sub-stacks described in the process correspond to several stacks. Certain lens transitions can belong to the same plate stack, which can be produced using the method according to the disclosure comprising steps (a) to (d).

According to a further aspect of the disclosure, the disclosure relates to a micro-optical unit for a multiple particle beam system produced according to a method as described above in a plurality of embodiment variants.

According to a further aspect of the disclosure, the disclosure relates to a micro-optical unit for a multiple particle beam system, for example for a multi-beam particle microscope. In this case, the micro-optical unit comprises a first multi-aperture plate comprising or consisting of metal and a second multi-aperture plate comprising or consisting of metal. The following in each case applies to the aperture diameters A of the first multi-aperture plate and the second multi-aperture plate: A ≥ 150 µm. Moreover, the following in each case applies to the thicknesses C of the first multi-aperture plate and the second multi-aperture plate: C ≥ 250 µm. The following applies to the plate distance D between the first multi-aperture plate and the second multi-aperture plate: D ≥ 30 µm.

The described micro-optical unit can therefore be a relatively large micro-optical unit, which moreover is manufactured from metal. Production of such a micro-optical unit using the known planar integration techniques either is not possible at all or only possible with considerable amounts of time.

According to a further aspect of the disclosure, the disclosure relates to a multiple particle beam system, for example to a multi-beam particle microscope, having a micro-optical unit as described above.

According to an embodiment of the disclosure, a voltage U with U ≥ 250 V, such as U ≥ 300 V or U ≥ 350 V, can be applied to the first multi-aperture plate and/or to the second multi-aperture plate of the micro-optical unit during the operation of the multiple particle beam system. The application of such high voltages to a multi-aperture plate is normally not possible with the known micro-optical units, which are produced via planar integration techniques. Instead, voltages of the order of less than 200 V only can be used in those cases. Otherwise, there can be flashovers between different multi-aperture plates. Comparatively large plate distances D are involved when using the aforementioned high voltages of sometimes significantly more than 250 V. Although this cannot normally be achieved via grown-on insulator layers such as silicon oxide, it can be achieved via other production methods because the thicknesses of insulator layers are typically limited by the method in growing-on methods. It can then be particularly desirable that isolators, too, can be pierced (for example via laser drilling) via some of the described production methods or drilling methods according to the disclosure.

According to an embodiment of the disclosure, the multiple particle beam system moreover comprises a magnetic lens which during the operation of the multiple particle beam system is arranged downstream of the micro-optical unit in relation to the particle-optical beam path of the multiple particle beam system. In this case, in relation to the particle-optical beam path of the multiple particle beam system, the micro-optical unit has a final multi-aperture plate. This final multi-aperture plate is magnetically conductive, wherein the following relation applies to a relative permeability µᵣ of the material of the final multi-aperture plate: µᵣ ≥ 1000, such as µᵣ ≥ 10 000 or µᵣ ≥ 15 000. In this case, during the operation of the multiple particle beam system, the final multi-aperture plate of the micro-optical unit is arranged within the magnetic field created by the magnetic lens. As a result, during the operation of the multiple particle beam system, individual particle beams passing through the micro-optical unit can enter the magnetic field of the magnetic lens abruptly, which can open up an option for setting an azimuthal tilt of the individual particle beams.

According to an embodiment of the disclosure, the multiple particle beam system furthermore comprises a controller which is configured to control the magnetic lens and set its magnetic field strength. Furthermore, the controller is configured such that an azimuthal tilt of individual particle beams, which pass through the magnetic lens during operation, is set by changing the magnetic field strength of the magnetic lens. Such a setting option is of particular interest for an inspection of samples with a high aspect ratio. When examining samples with a high aspect ratio, it is often of relevant that the inspecting individual particle beams are incident on the sample surface in telecentric fashion in order to be able to ideally scan the structures with the high aspect ratio. Another exemplary application option is samples that are located within the magnetic field of an objective lens system (magnetic immersion lenses). Charged particles undergo rotation or Larmor rotation in the magnetic field due to the Lorentz force. Should a sample to be scanned still be situated within the magnetic field, a rotation of the charged particles in the magnetic field is incomplete and the azimuthal velocity component of the charged particles is not yet zero upon incidence on the sample. This can lead to an azimuthal tilt of individual particle beams. Such a tilt can be compensated via the described arrangement of a final multi-aperture plate with high magnetic conductivity within a magnetic field of a magnetic lens such as a field lens.

There are also applications in which individual charged particle beams are intended to pass through e.g. an objective lens in slightly tilted fashion. For example, this can be the case if a sample surface is tilted relative to the particle-optical axis Z, i.e. this axis Z is not exactly perpendicular to the sample surface.

Moreover, it is for example possible to correct certain aberration terms of the objective lens via the described arrangement or via this passive multi-deflector.

According to an embodiment, the material of the final multi-aperture plate is Permenorm^{®}. However, other materials are also possible. These include, for example, soft-magnetic standard nickel-iron alloys with a nickel content of approximately 50 %. These alloys combine both high saturation flux density and high maximum permeabilities.

Various magnetically conductive materials are known with a relative permeability of µᵣ ≥ 1000 that are suitable for the final multi-aperture plate. These include inter alia soft-magnetic standard materials such as pure iron (e.g. Vacofer^{®}), nickel-iron alloys with an approximately 75 % nickel content such as Mu Metal, Permalloy or Supermalloy, nickel-iron alloys with an approximately 50 % nickel content such as e.g. Permenorm^{®}, cobalt-iron alloys with an approximately 50 % cobalt content such as e.g. Vacoflux^{®}, or silicon-iron alloys with an approximately 3 % silicon content such as e.g. Trafoperm^{®}. These materials are also commercially available as thin membranes, for example with a thickness of 25 µm, 50 µm, 100 µm or 250 µm. On account of the low thickness, plates made of such materials are suitable as a matter of principle for a final multi-aperture plate.

According to a further aspect of the disclosure, the disclosure relates to a multiple particle beam system comprising the following:
a particle source for creating a charged particle beam;
a multi-beam generator that is passed by the charged particle beam, forming a plurality of first individual charged particle beams that form a first field;
a first particle-optical unit with a first particle-optical beam path, configured to image the created first individual particle beams onto an object plane such that the first individual particle beams impinge on an object at incidence locations that form a second field;
an objective lens, for example a magnetic objective lens, through which the first individual particle beams pass; and
a controller;
wherein the multi-beam generator comprises a micro-optical unit having a plurality of successively arranged multi-aperture plates, which are successively passed by the first individual charged particle beams in each case, wherein, in relation to the particle-optical beam path, the micro-optical unit comprises a final multi-aperture plate which is magnetically conductive, wherein the following relation applies to a relative permeability µᵣ of the material of the final multi-aperture plate: µᵣ ≥ 1000, for example µᵣ ≥ 10 000 or µᵣ ≥ 15 000,
wherein the first particle-optical unit comprises a magnetic field lens,
wherein, during the operation of the multiple particle beam system, the final multi-aperture plate of the micro-optical unit is arranged within a magnetic field created by the magnetic field lens,
wherein the controller is configured to control the magnetic field lens and set its magnetic field strength, and
wherein the controller is furthermore configured such that an azimuthal tilt of the first individual charged particle beams when impinging on the object and/or when passing through the objective lens is set via a change in the magnetic field strength of the magnetic field lens.

In turn, it is possible here that the micro-optical unit of the multi-beam generator is produced according to the described method for producing a micro-optical unit for a multiple particle beam system.

According to an embodiment of the disclosure, the final multi-aperture plate as regards its central aperture and the magnetic field lens are arranged centred to each other. This centration can help facilitate setting the azimuthal tilt or its precision.

According to an embodiment of the disclosure, the z-component Bz of the magnetic field B on the particle-optical axis Z assumes a value at the final multi-aperture plate, to which value the following relation applies: 0.1 mT ≤ Bz ≤ 10.0 mT, such as 1.0 mT ≤ Bz ≤ 10.0 mT. For example, given a magnetic field, a distance dFF between the final multi-aperture plate and the lens centre of the magnetic lens can be set to this end such that the relation for the magnetic field Bz is satisfied.

According to an embodiment of the disclosure, the magnetic field strength B of the magnetic field lens is varied by a maximum of +/-50 % of its nominal value for the purpose of setting the azimuthal tilt of the first individual particle beams. This variation in the magnetic field strength thus can be a fine adjustment. It is possible that a lookup table for different presets of magnetic field strengths B, for example for different operating points of a multiple particle beam system, is stored in a memory of the multiple particle beam system, and this allows targeted setting of the value for an azimuthal tilt of first individual particle beams. In this case, a nominal value is defined such that the nominal value can correspond to the case of a fully corrected azimuthal beam tilt at the object or at the sample surface or at a wafer surface.

According to an embodiment of the disclosure, the material of the final multi-aperture plate is Permenorm^{®}. However, other materials are also possible, for example other soft-magnetic standard nickel-iron alloys with a nickel content of approximately 50 %.

According to an embodiment of the disclosure, the multiple particle beam system is a multi-beam particle microscope. However, the multiple particle beam system can also be a different multiple particle beam system, for example a lithography system.

According to an embodiment of the disclosure, the multiple particle beam system furthermore comprises the following:
a detection system having a plurality of detection regions that form a third field;
a second particle-optical unit having a second particle-optical beam path, configured to image second individual charged particle beams, which emanate from the incidence locations in the second field, on the third field of the detection regions of the detection system; and
a beam splitter arranged in the first particle-optical beam path between the multi-beam particle source and the objective lens and arranged in the second particle-optical beam path between the objective lens and the detection system;
wherein both the first individual particle beams and the second individual particle beams pass through the objective lens.

According to an embodiment of the disclosure, a second micro-optical unit having a plurality of successively arranged multi-aperture plates, which are successively passed by the second individual charged particle beams in each case, is provided in the second particle-optical beam path. In this case, in relation to the particle-optical beam path, the micro-optical unit has a final multi-aperture plate which is magnetically conductive, wherein the following relation once again applies to a relative permeability µᵣ of the material of the final multi-aperture plate: µᵣ ≥ 1000, such as µᵣ ≥ 10 000 or µᵣ ≥ 15 000. Furthermore, the second particle-optical unit comprises a magnetic projection lens. In this case, during the operation of the multiple particle beam system, the final multi-aperture plate of the second micro-optical unit is arranged within a magnetic field created by the magnetic projection lens. In this embodiment of the disclosure, the controller is configured to control the magnetic projection lens and to set its magnetic field strength. In this case, the controller is furthermore configured such that an azimuthal tilt of the second individual charged particle beams when striking the detection regions and/or when passing through a contrast aperture arranged level with a crossover of the second individual particle beams is set via a change in the magnetic field strength of the magnetic projection lens. In turn, the second micro-optical unit having the final multi-aperture plate can in this case be produced again in accordance with the method according to the disclosure for producing a micro-optical unit for a multiple particle beam system, as described above in several embodiment variants. With the described configuration of the multiple particle beam system, it is possible to realize a multi-deflector not only in the first particle-optical beam path of a multiple particle beam system but also in a second particle-optical beam path of the multiple particle beam system. The described effects and embodiments can be realized in a manner analogous to the described effects and embodiments in the first particle-optical beam path.

Various embodiments and aspects of the disclosure can be combined wholly or partly with one another, provided that no technical contradictions arise as a result.

### BRIEF DESCRIPTION OF THE DRAWINGS

The disclosure will be understood even better with reference to the accompanying figures. In the figures:

FIG. 1: schematically shows a multiple particle beam system;

FIG. 2: schematically shows a structure of a micro-optical unit;

FIGS. 3A-3D: schematically show an alignment issue in the case of multi-aperture plates;

FIGS. 4A-4D: schematically show method steps of a production method according to the disclosure for a micro-optical unit;

FIG. 5: shows a flowchart of a production method according to the disclosure;

FIGS. 6A-6F: schematically show method steps of a production method according to the disclosure;

FIGS. 7A-7B: schematically show method steps of a production method according to the disclosure;

FIG. 8: schematically shows aspects of a production method according to the disclosure;

FIGS. 9A-9D: schematically show method steps of a production method according to the disclosure;

FIGS. 10A-10B: schematically show a Manhattan electrode and a multi-aperture plate created therewith;

FIGS. 11A-11C: schematically show multi-aperture plates of a micro-optical unit;

FIGS. 12A-12B: schematically show aspects of a production method for a micro-optical unit;

FIG. 13: shows a further flowchart of a production method according to the disclosure;

FIGS. 14A-14B: schematically shows particle-optical imaging through a symmetric and through an asymmetric magnetic lens; and

FIG. 15: schematically illustrates an arrangement having a micro-optical unit and having a magnetic lens for the realization of a multi-deflector.

### DETAILED DESCRIPTION

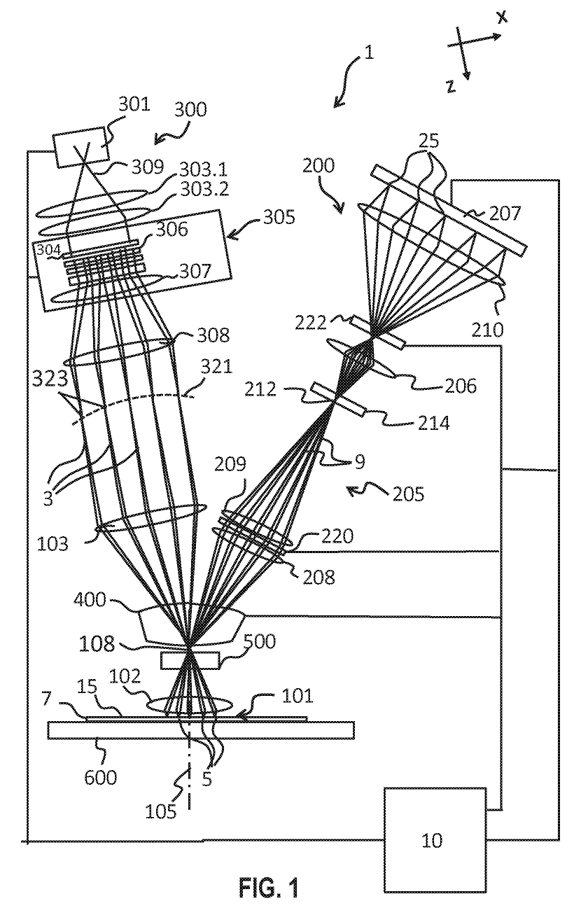

FIG. 1 schematically shows a multiple particle beam system 1 in the form of a multi-beam particle microscope 1. The multi-beam particle microscope 1 comprises a beam generating apparatus 300 having a particle source 301, for example an electron source. A divergent particle beam 309 is collimated by a sequence of condenser lenses 303.1 and 303.2 and incident on a multi-aperture arrangement 305, which forms a micro-optical unit. The multi-aperture arrangement 305 comprises several multi-aperture plates 306 and a field lens 308. A plurality of individual particle beams 3 or individual electron beams 3 are created by the multi-aperture arrangement 305. Midpoints of apertures in the multi-aperture plate arrangement are arranged in a field which is imaged on a further field formed by beam spots 5 in the object plane 101. The pitch between the midpoints of apertures of a multi-aperture plate 306 can be for instance 5 µm, 100 µm and 200 µm. The diameters A of the apertures are smaller than the pitch of the midpoints of the apertures; examples of the diameters are 0.2 times, 0.4 times and 0.8 times the pitches between the midpoints of the apertures.

The multi-aperture arrangement 305 and the field lens 308 are configured to create a plurality of focal points 323 of primary beams 3 in a raster arrangement on a surface 321. The surface 321 need not be a plane surface but rather can be a spherically curved surface in order to account for a field curvature of the subsequent particle-optical system.

The multi-beam particle microscope 1 further comprises a system of electromagnetic lenses 103 and an objective lens 102, which image the beam foci 323 from the intermediate image surface 325 in the object plane 101 with reduced size. In between, the first individual particle beams 3 pass through the beam splitter 400 and a collective beam deflection system 500, via which the plurality of the first individual particle beams 3 are deflected during operation and the image field is scanned. The first individual particle beams 3 incident in the object plane 101 for example form a substantially regular field, wherein the pitch between adjacent incidence locations 5 can be 1 µm, 10 µm or 40 µm, for example. For instance, the field formed by the incidence locations 5 can have a rectangular or hexagonal symmetry.

The object 7 to be examined can be of any desired type, for instance a semiconductor wafer or a biological sample, and can comprise an arrangement of miniaturized elements or the like. The surface 15 of the object 7 is arranged in the object plane 101 of the objective lens 102. The objective lens 102 can comprise one or more electron-optical lenses. For instance, this can be a magnetic objective lens and/or an electrostatic objective lens.

The primary particles 3 incident on the object 7 generate interaction products, for example secondary electrons, backscattered electrons or primary particles, which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 downstream of the objective lens 102 and are guided to a projection system 200. The projection system 200 comprises an imaging system 205 with projection lenses 208, 209 and 210, a contrast stop 214 and a multi-particle detector 207. Incidence locations 25 of the second individual particle beams 9 on detection regions of the multi-particle detector 207 are located with a regular pitch in a third field. Exemplary values are 10 µm, 100 µm and 200 µm.

The multi-beam particle microscope 1 further comprises a computer system or a control unit 10, which in turn can have a single-part or multi-part design and which is designed both to control the individual particle-optical components of the multi-beam particle microscope 1 and to evaluate and analyse the signals obtained by the multi-detector 207 or the detection unit.

Further information relating to such multi-beam particle beam systems or multi-beam particle microscopes 1 and component parts used therein, such as, for instance, particle sources, multi-aperture plate and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is fully incorporated in the present application by reference.

The multi-aperture arrangement 305 forms a micro-optical unit 305, via which, in the example shown, during the operation of the multiple particle beam system 1, the plurality of the first individual particle beams 3 are initially created at the first of the multi-aperture plates (so-called filter plate) and also actively formed at further multi-aperture plates. The micro-optical unit 305 itself can be configured differently here.

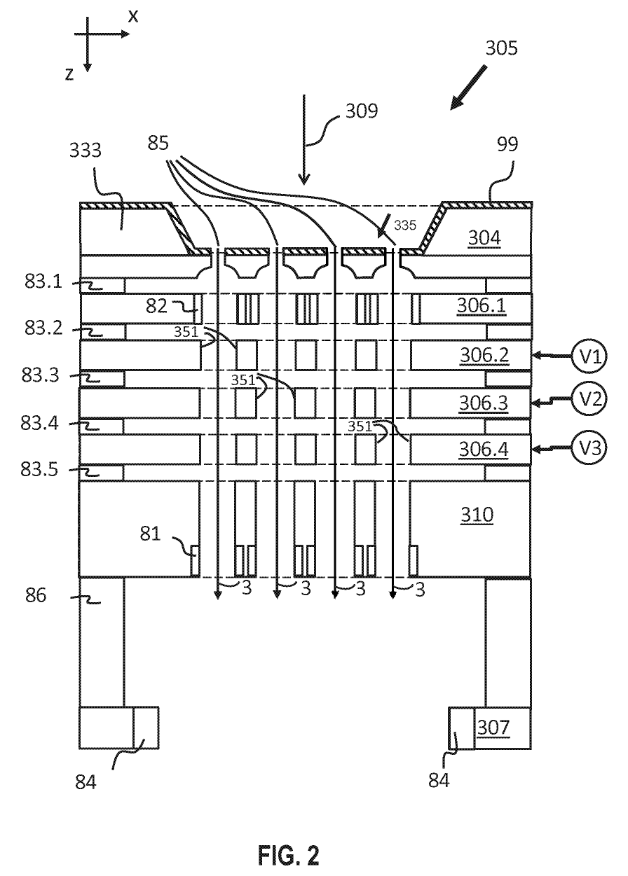

FIG. 2 shows, by way of example, a micro-optical unit 305 which is designed as a multi-beam generator 305. In the illustrated example, the multi-beam generator 305 comprises a sequence with six multi-aperture plates 304, 306.1, 306.2, 306.3, 306.4 and 310 and a global condenser lens 307 in the z-direction, which corresponds to the direction of propagation of the individual particle beams 3. Each of the multi-aperture plates 304, 306.1 to 306.4 and 310 comprises a plurality of apertures 351, which are passed by the plurality of individual particle beams 3 in each case. The cross section through the apertures 351 is not to scale in FIG. 2.

The plurality of multi-aperture plates 304, 306.1, 306.2, 306.3, 306.4 and 310 are spaced apart from one another by spacers 306.1, 306.2, 306.3, 306.4 and 310.1 to 83.5. Moreover, a spacer 86 is provided between the final multi-aperture plate 310 and the global lens electrode 307. As a result of the incidence of a collimated particle or electron beam 309, the plurality of first individual particle beams 3 are created during the passage through the first multi-aperture plate 304, which is also referred to as filter plate or pre-aperture plate. The pre-aperture plate 304 comprises a metallic layer 99 on its beam input side, for stopping and absorbing the electrons of the electron beam 309 incident thereon around the plurality of the apertures 85. In this case, the material of the pre-aperture plate 304 is produced from a conductive material in the example shown, for example from doped silicon, and is at earth potential.

In the example shown in FIG. 2, the next multi-aperture plate is a multi-stigmator plate 306.1. The multi-stigmator plate 306.1 comprises a plurality of four or more electrodes 82, for example eight electrodes for each of the apertures. Different voltages, for example ranging between -20 V and +20 V, can be applied to each of these electrodes during the operation of the multi-beam particle microscope 1 and hence individually influence each individual particle beam 3. For example, it is possible with an antisymmetric voltage difference to deflect each individual particle beam 3 up to a few µm in each direction in order to pre-correct a distortion correction of the illuminating unit 100. An astigmatism pre-correction for each individual particle beam 3 can likewise be undertaken. Via an offset voltage, each multi-pole element can additionally act as an Einzel lens.

In general, the multi-aperture plates 306.2, 306.3 and 306.4 can be any desired trajectory correction plates with monolithic design and with a respective voltage V1, V2 and V3 applied thereto in the example shown. It is also possible that the multi-aperture plates 306.2, 306.3 and 306.4 form an Einzel lens array. Different apertures 351 in the same multi-aperture plate 306.2, 306.3 and 306.4 can have an identical design or different designs, for example have different diameters in order to take into account a field dependence of the correction in the trajectory correction of the individual particle beams 3.

The multi-aperture plate 310 is a two-layer multi-aperture plate and comprises a plurality of ring electrodes 79 for the plurality of apertures, wherein each ring electrode is configured to individually change or correct a focal position of the first individual particle beam 3 passing therethrough. In this case, the upper layer is insulated from the layer or ply with the ring electrodes 79 and produced from a conductive material such as doped silicon, for example.

The field lens 307 comprises a ring electrode 84, to which a high voltage of for example 3 kV to 20 kV can be applied, for example 12 kV to 17 kV. In the example shown, the condenser lens 307 provides a global electrostatic lens field for global focusing of the plurality of individual particle beams 3.

The micro-optical unit 305 or its multi-aperture plates shown in FIG. 2 can in general be produced via known production methods or via planar integration techniques. However, at least a few multi-aperture plates, for example the multi-aperture plates 306.2, 306.3 and 306.4, can also be produced via the production method according to the disclosure. On account of the exceptional performance of such multi-aperture plates 306.2, 306.3 and 306.4 produced according to the disclosure (applicability of quite high voltages V, V2, V3 and relatively large plate spacings or large thickness of spacers/isolators 83.2, 83.3, 83.4, 83.5), it is also possible that e.g. the multi-aperture plate 310 with the ring electrodes 81 becomes superfluous as a result.

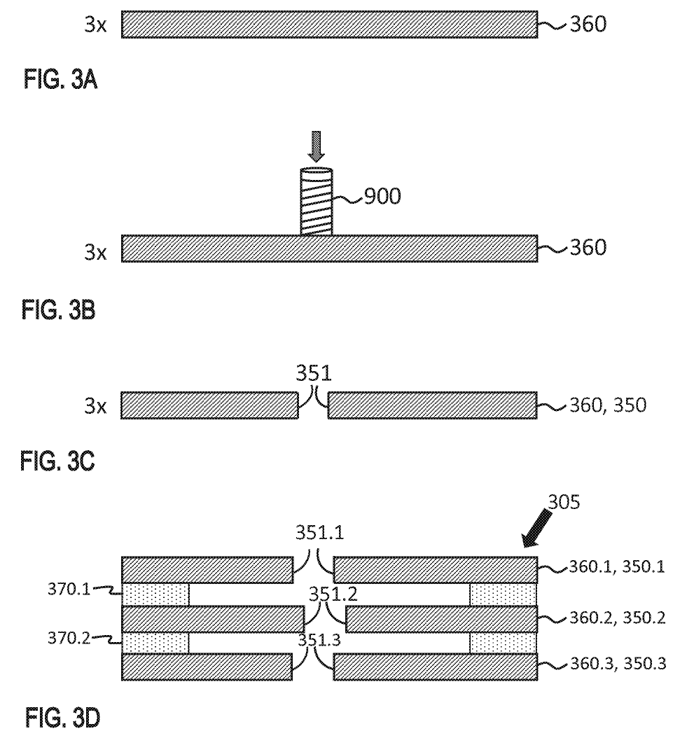

FIGS. 3A-3D show schematically an alignment issue in the case of multi-aperture plates 350 which have each been produced independently of one another, i.e. on its own in each case. FIG. 3A schematically shows the provision of three plates 360 without openings. FIG. 3B schematically shows the use of a drilling mechanism 900, which in general can be of any kind. In this respect, FIGS. 3A-3D only consider the principle. The effective direction of the drilling mechanism 900 is indicated schematically in FIG. 3B by way of the arrow. The drilling mechanism 900 forms openings 351 in the plate 360, whereby a multi-aperture plate 350 emerges from the plate 360. It should be observed that, for reasons of clearer illustration, FIGS. 3A-3D depict only one opening 351 but a multi-aperture plate 350 naturally contains several openings 351. FIG. 3D now illustrates that the three multi-aperture plates 350.1, 350.2 and 350.3 are assembled to form a multi-aperture arrangement 305 or a micro-optical unit 305. To this end, the conductive multi-aperture plates 350.1, 350.2 and 350.3 are aligned with one another, and also fixed and insulated. In the example shown, this is realized by the spacers 370.1 and 370.2. It is the case here that the openings 351.1 and 351.2 and 351.3 are not arranged exactly on top of one another, i.e. not arranged centrally on top of one another. Thus, they are not aligned flush. An exact arrangement or orientation with respect to one another as regards the openings 351.1, 351.2, 351.3 in the multi-aperture plates 350.1, 350.2 and 350.3 is very difficult, if not impossible. This applies especially if the multi-aperture plates 350.1, 350.2 and 350.3 are made of metal: This is because they do not transmit visible light or infrared radiation in that case, and an optically based alignment, as is typically used in die bonders, is very difficult. Thus, it is not readily easily possible to replace semiconductor-based plates in a multi-aperture arrangement 305 with metal plates.

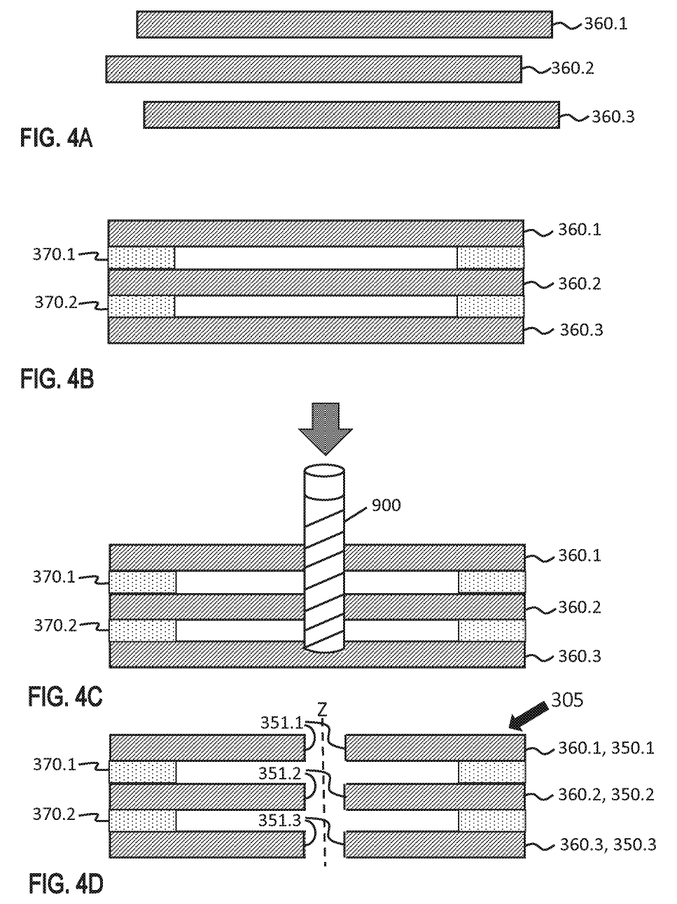

However, the production method according to the disclosure offers a solution approach in which plates made of metal firstly can be used for the production of a micro-optical unit 305 and secondly can also be aligned precisely enough. FIGS. 4A-4D schematically shows method steps of a production method according to the disclosure for a micro-optical unit 305:

FIG. 4A initially shows three plates 360.1, 360.2 and 360.3 for the micro-optical unit 305, which are not only conductive in the example shown but also made of metal.

FIG. 4B shows the arrangement of the plates 360.1, 360.2 and 360.3 relative to one another. In this case, the plates 360.1, 360.2 and 360.3 are fixed relative to one another and electrically insulated from one another by spacers 370.1 and 370.2. The spacers 370.1 and 370.2 can be produced from silicon oxide, for example.

FIG. 4C now schematically shows the piercing of the plate stack having the plates 360.1, 360.2 and 360.3 via a drilling mechanism 900. This is only depicted schematically in FIG. 4C; the drilling direction is indicated by the arrow. It is now relevant that the entire plate stack is pierced in general by the same drilling mechanism 900 in a single attempt and during the same drilling process.

FIG. 4D shows the result of the drilling process: The apertures 351.1, 351.2 and 351.3 are perfectly aligned to one another and the centres of the apertures 351.1, 351.2 and 351.3 are located centrally on the axis Z in the example shown. Once again, FIGS. 4A-4D depict a sequence of apertures 351.1, 351.2 and 351.3 purely by way of example; naturally, however, there are several apertures or sequences of apertures present in the multi-aperture plates 350.1, 350.2 and 350.3.

Moreover, it is conceivable that it is not only the plates 360.1, 360.2 and 360.3 but also insulating plates or layers that are pierced via the drilling mechanism 900. Whether this is possible depends only on the drilling method used.

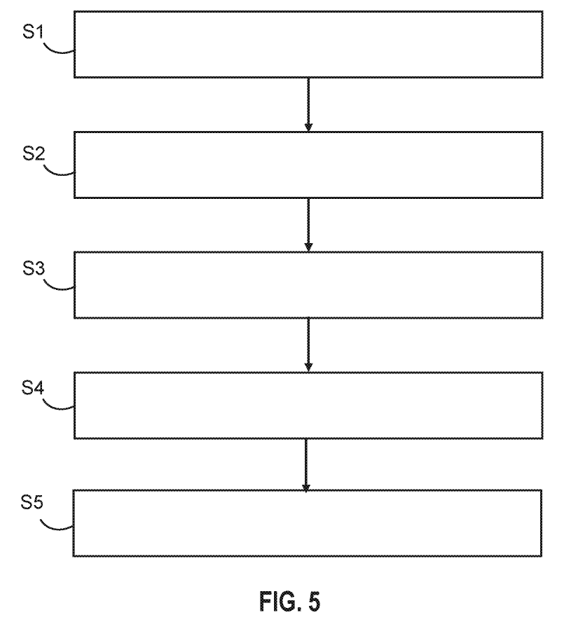

FIG. 5 schematically shows a flowchart of a production method according to the disclosure for a micro-optical unit 305 for a multiple particle beam system 1: A first plate 360.1 of the micro-optical unit 305, which is electrically conductive, is initially provided in a method step S1.

A second plate 360.2 of the micro-optical unit 305, which is electrically conductive, is provided in a method step S2.

A plate stack is created in a method step S3: The creation of a plate stack comprises the step of stacking the first plate 360.1 of the micro-optical unit 305 and the second plate 360.2 of the micro-optical unit 305 on top of each other, wherein the first plate 360.1 of the micro-optical unit 305 and the second plate 360.2 of the micro-optical unit 305 are fixed in the plate stack relative to each other and electrically insulated from each other. For example, this can be realized by using insulating spacers 370.1, 370.2.

Then, method step S4 sees implementation of the following: piercing of the entire created plate stack having at least the first plate 360.1 and the second plate 360.2 of the micro-optical unit 305, and thereby creating both a first plurality of apertures 351.1 in the first plate 360.1 of the micro-optical unit 305 and a second plurality of apertures 351.2 in the second plate 360.2 of the micro-optical unit 305. As a result, the sequence of apertures 350.1, 350.2 in the plates 360.1, 360.2 of the plate stack created during the same drilling process has an exact alignment, specifically in process-inherent fashion. Optionally, the plate stack further can comprise at least one further plate and thus at least a third plate 360.3 of the micro-optical unit 305, whicunit 305ctrically conductive. In this case, the third plate 360.3 of the micro-optical unit 305 is fiunit 305tive to the first plate 360.1 of the micro-optical unit 305 and the second plate 360.2 of the micro-optical unit 305 and is electrically insulated therefrom. The third plate of the micro-optical unit 305 is also pierced during the implementation of method step S4, and so a third plurality of apertures 351.3 are created thereby in the third plate 360.3 of the micro-optical unit 305. One or more of the aforementioned plates in the micro-optical unit 305 can comprise or consist of a metal. According to an embodiment of the disclosure, all pierced plates comprise or consist of metal. However, it is also possible that other plates which are not conductive but comprise or consist of an insulating material, for example of silicon dioxide, are provided in addition to the conductive plates.

In method step S4, the plate stack can be pierced in different ways: Examples of the drilling methods include laser drilling, micro-EDM drilling, mechanical high-speed micro-drilling, vibration drilling, ultrasonic drilling or the use of a focused ion beam (FIB), for example. With regard to the details of these methods, reference is made to the explanations given in the general part of the description of the disclosure.

Optionally, the plate stack can be flushed, and drilling material can be removed through flushing holes in the first plate 360.1 of the micro-optical unit 305 and in the second plate 306.2 of the micro-optical unit 305 in a further method step S5. In this case, the following relation can apply to a diameter S of the flushing holes in relation to the diameter A of the apertures in the first plate 306.1 of the micro-optical unit 305 and in the second plate 306.2 of the micro-optical unit 305: S ≥ 10A, such as S ≥ 100A.

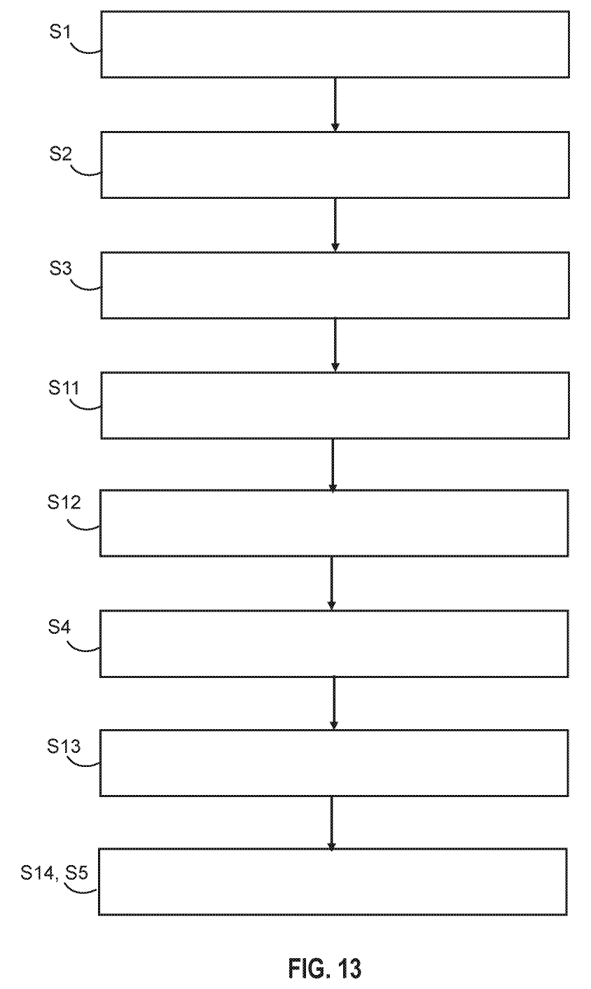

A modified production method for a micro-optical unit 305 of a multiple particle beam system 1 is shown in the flowchart in FIG. 13: In this case, method steps S1 to S3 are initially implemented as described above. Before the plate stack is pierced according to step S4, the described exemplary embodiment sees an intermediate space between the first plate 306.1 of the micro-optical unit 305 and the second plate 306.2 of the micro-optical unit 305 being filled with a liquid flushing agent in step S11 and the flushing agent being cooled, and hence the flushing agent being solidified, in step S12. For example, temperature control can be realized by way of the method being carried out within a process chamber, the internal temperature of which can be set, or the liquid being supplied in a heated state and subsequently cooling on its own accord. The entire plate stack is then pierced in step S4. By arranging/providing the solidified flushing agent, forces acting on the plates 306.1 and 306.2 during the piercing process can be better absorbed, distributed and dissipated. This can help to better prevent bending of the plates 306.1 and 306.2. In a further method step S13, the flushing agent is heated and hence the flushing agent is liquefied. For example, the entire plate stack can be heated in the process, and, in so doing, the flushing agent is also heated. In a further method step S14, the flushing agent, now in liquid form again, is removed from the intermediate space. The flushing holes described above can be used for the filling with the flushing agent and for the removal of the flushing agent.

Optionally, it is also possible that the entire plate stack is annealed in a further method step. This may be desirable in the case of a magnetically conductive final multi-aperture plate 350.f in order to ensure the magnetic conductivity thereof, for example for use of the micro-optical unit 305 in combination with a magnetic lens 308 in a multiple particle beam system 1 as a magnetic multi-deflector.

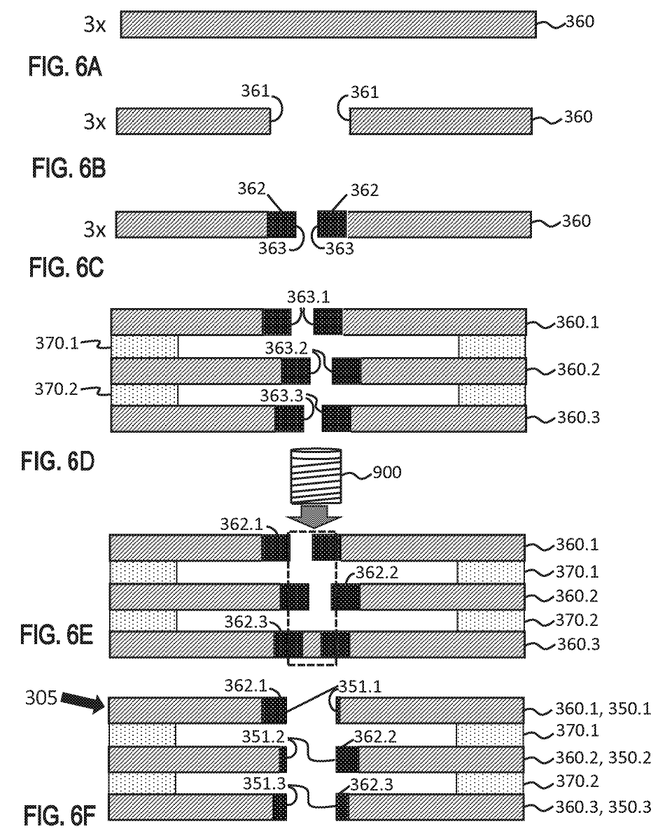

FIGS. 6A-6F schematically show method steps of a production method according to the disclosure. In the exemplary embodiment shown in FIGS. 6A-6F, the plates 360 of the micro-optical unit 305 are not conductive or not conductive everywhere. Their conductivity is only provided in sections, to be precise in the region around the apertures 351 that are yet to be formed:

Specifically, three plates 360, non-conductive per se, are initially provided for the micro-optical unit 305. The plates 360 can have an insulating material as base material, for example a ceramic as base material. Coarse apertures 361 can now be formed in these plates 360. The coarse apertures 361 are larger than the apertures 362 to be ultimately produced in the micro-optical unit 305.

The coarse apertures 362 are metallized in a further method step (cf. FIG. 6C). For example, metallization of the coarse apertures 361 can be implemented via sputtering or via electroplating. In the process, conductive regions 363 are formed around the coarse apertures or adjacent to the coarse apertures 362. These in turn have openings 363. Their diameter is smaller than the diameter of the final apertures 351 of the micro-optical unit 305.

In a further method step, the plates 360.1, 360.2 and 360.3 with the metallized coarse apertures 361 are fixed relative to one another and arranged in a manner electrically insulated from one another. In this case, the spacers 370.1 and 370.2 can be electrically insulating; however, this need not necessarily be the case since the plate material of the plates 360.1, 360.2 and 360.3, as a ceramic, can already be sufficiently insulating. The openings 363.1, 363.2 and 363.3 are not perfectly aligned to one another. However, this need not yet be the case at this stage of the production method:

This is because, as shown in FIG. 6E, the metallized coarse apertures 361 or the conductive regions 362.1, 362.2 and 362.3 are then pierced. Once again, a drilling mechanism 900 and its direction of movement in this respect are schematically indicated in FIG. 6E.

As a result – as depicted in FIG. 6F. – apertures 351.1, 351.2 and 351.3 which are perfectly aligned with one another or are aligned exactly to one another in process-inherent fashion are formed.

Thus, the production method described in FIGS. 6A-6F not only allows the production of monolithic multi-aperture plates 350.1, 350.2 and 350.3 that are already (completely) conductive per se; instead, it is also possible to realize ring electrodes via the production method according to the disclosure. In this case, the ring electrodes are formed by the conductive regions 362.1, 362.2 and 362.3 in the example shown. The supply of lines to the individual ring electrodes is to be realized in a further method step; this is more complex than in the case of monolithic multi-aperture plates 350 but can also be realized. For example, a metal printing process prior to the plate stack assembly lends itself to this end. For example, it is also possible that conductor tracks are applied by a combination of sputtering and electroplating.

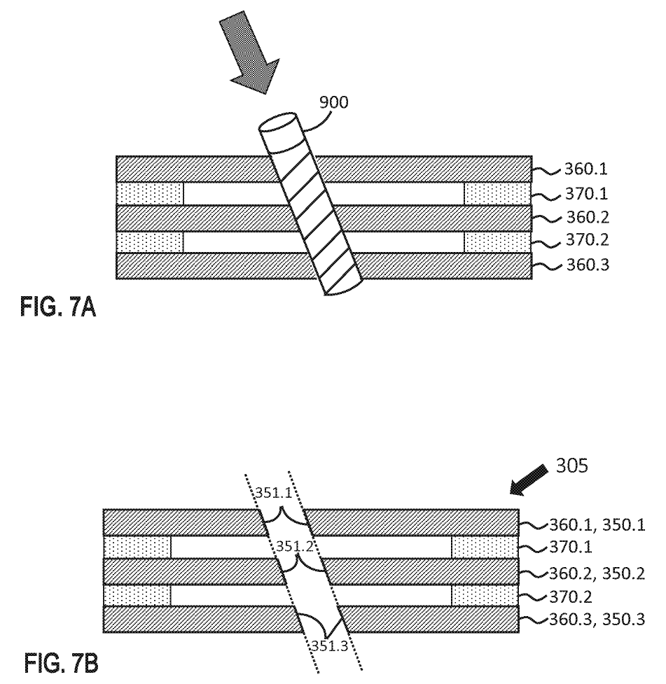

FIGS. 7A-7B schematically shows method steps of a production method according to the disclosure for a micro-optical unit 305. For example, the plate stack having the plates 360.1, 360.2 and 360.3 shown in FIG. 7A can be produced as described in connection with FIGS. 4A and 4B. Unlike what is shown in connection with FIG. 4C, however, the piercing of the plate stack in FIG. 7A now is different, specifically with regard to the drilling direction: This is because the plate stack is pierced at an angle. The resulting angled apertures 351.1, 351.2 and 351.3 are also aligned exactly flush with one another, as indicated by the dotted guide lines in FIG. 7B. However, the apertures 351.1, 351.2 and 351.3 are not exactly circular but slightly elliptical in the event of this angled piercing. The degree of ellipticity depends on the degree of inclination during piercing in relation to the normal of the plate stack.

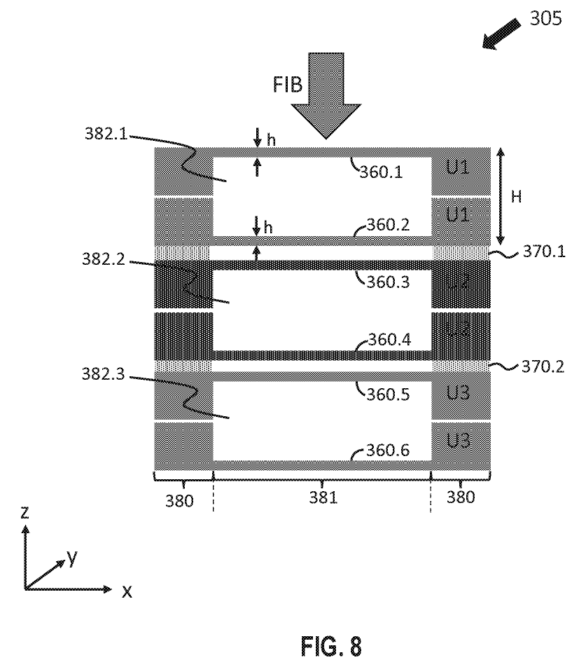

FIG. 8 schematically shows aspects of a production method according to the disclosure, wherein the plate stack is pierced using a focused ion beam (FIB). The plate stack shown comprises a total of six membranes 360.1, 360.2, 360.3, 360.4, 360.5 and 360.6, which are clamped in a frame. This is illustrated by reference signs 380, which indicate a frame region, and reference sign 381, which indicates a membrane region.

The illustrated plate stack should have the functionality of an Einzel lens, for example, after the entire plate stack has been pierced. For this reason, voltages U1, U2 and U3 are schematically indicated in FIG. 8. However, two membranes with the small thicknesses h are provided instead of a single plate 360 with the overall height H over the entire plate width. In this case, the corresponding voltage is applied in each case to the lower and the upper membrane. From an electron-optical point of view, the fact that cavities 382.1, 382.2 and 382.3 are provided between the membranes 360.1 and 360.2, between membranes 360.3 and 360.4 and between membranes 360.5 and 360.6 makes no significant difference. Insulating spacers 370.1 and 370.2 are in turn arranged between the respectively associated membrane pairs in a known manner.

In the event of the plate stack being pierced, the focused ion beam can now be used in the same drilling process, starting from the top, to pierce first the topmost membrane 360.1, then the next membrane 360.2 and so on, to be precise once again, in general, in the same method step or in such a way that the position of the FIB column need not be changed, at least not in the x-direction or y-direction, i.e. the x,y-positions of the FIB column and hence also the x,y-positions of the apertures 351 to be created are fixed. The fact that only the thin membrane sections each of height h are to be pierced can take into account the fact that a focused ion beam has only a relatively small depth of focus and can therefore only pierce relatively thin layers. Piercing the entire plate stack as shown in FIG. 8 is therefore particularly suitable for plate stacks with a small overall height, for example up to a height of a few micrometres.

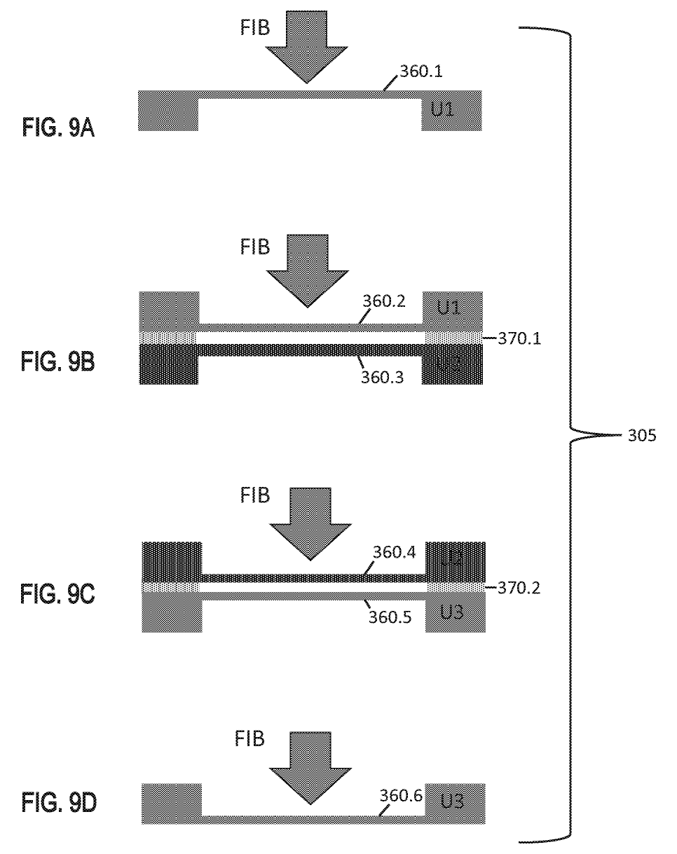

The procedure shown in FIGS. 9A-9D represent a solution for cases in which the plate stack has overall a greater height and the restricted depth of focus of the focused ion beam becomes the issue. The overall stack with the plates 360.1 to 360.6 is divided into four sub-stacks. For example, the plates 360.2 and 360.3 and the plates 360.4 and 360.5 respectively form independent stacks in the sense of the definition found in Claim 1. The individual stacks or sub-stacks are now pierced separately in each case via the FIB or via the focused ion beam. In this case, the stack according to FIG. 9B forms a stack in which a lens transition occurs. Here, the alignment of the apertures created in the plates 360.2 and 360.3 is relevant. The same applies to the lens transition between the plates 360.4 and 360.5, as shown in FIG. 9C. By contrast, the transitions within the same lens are not so relevant. Therefore, it is possible to assemble the sub-stacks following the separate piercing of the sub-stacks (FIGS. 9B and 9C) and of the individual plates or membranes (FIGS. 9A and 9D) without any appreciable loss of performance of the micro-optical unit 305 and to make a corresponding alignment here. This assembly of the sub-stacks is indicated by the bracket in FIGS. 9A-9D. This in turn results in the micro-optical unit 305.

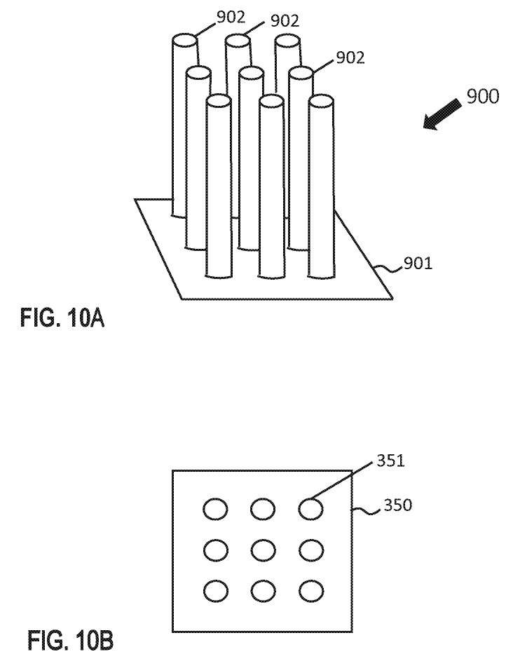

In general, it is possible that the plurality of apertures in the plates in a plate stack are created successively. However, it is also possible that at least some of the plurality of apertures in the plates are created simultaneously. An example for this is shown in FIGS. 10A-10B. FIG. 10A shows a Manhattan-type electrode as drilling mechanism 900. It comprises a plurality of electrodes 902 arranged on a base element 901. In general, the Manhattan-type electrode thus is a multi-electrode. It can be used to simultaneously create several openings at different positions in a plate 360 so to speak in batches. The result of the piercing process is shown in FIG. 10B: Shown is a multi-aperture plate 350 having a plurality of circular apertures 351, the arrangement of which corresponds to the arrangement of the electrodes 902.

The Manhattan-type electrode shown in FIGS. 10A-10B can be used in a micro-EDM method, for example. However, the principle can also be applied to other drilling methods.

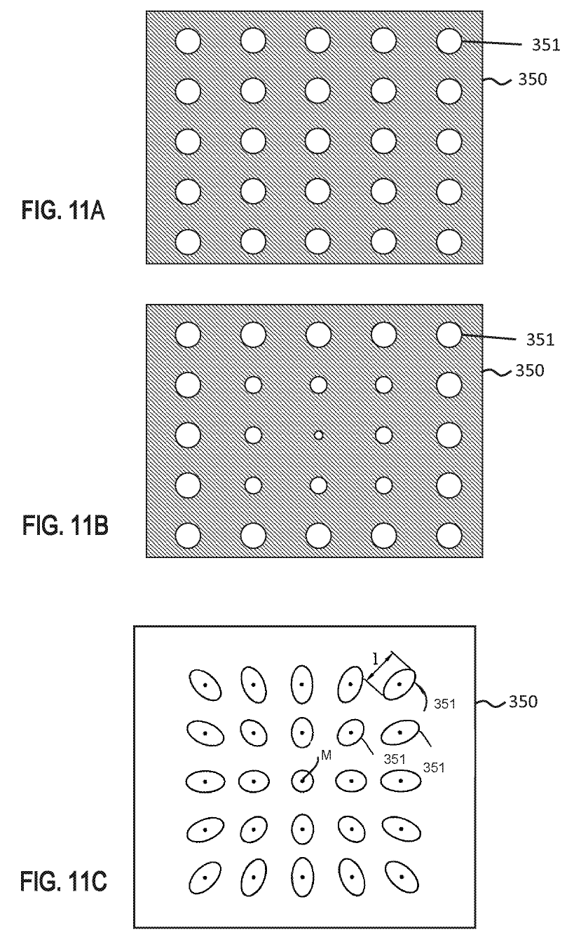

FIGS. 11A-11C schematically show several multi-aperture plates 350 of a micro-optical unit 305. In this context, FIG. 11A shows a plurality of round apertures 351, each with the same diameter and in a regular arrangement. FIG. 11B shows a multi-aperture plate 350 with circular apertures 351, the diameter of which however varies within the multi-aperture plate or depends on the position of the aperture in the respective plate 350. In the example shown, the diameter of the apertures 351 exhibits a radial dependence on the distance from the centre C in the multi-aperture plate 350.

FIG. 11C shows a multi-aperture plate 350 with elliptical apertures 351. Their longitudinal axis l varies depending on the centre M, to be precise in terms of orientation and size.

All multi-aperture plates 350 shown in FIGS. 11A-11C are monolithic aperture plates 350 to which only a single voltage is applied in each case. On account of the conductivity of the plates 350, the apertures 351 create an effect or lens effect, the magnitude of which then still depends only on the size and shape of the aperture.

In general, what holds true is that the shape of the apertures 351 in the plates 360, 350 in the plate stack can have a round, elliptical, n-fold or irregular shape. The apertures themselves can be arranged via a raster, for example via a hexagonal raster. However, they can also be arranged in a square or rectangular raster, for example.

According to one exemplary embodiment, adjacent apertures 351 in the plates in the plate stack have a distance B, to which the following applies: 70 µm ≤ B ≤ 400 µm, such as 90 µm ≤ B ≤ 400 µm, or 120 µm ≤ B ≤ 400 µm.

For example, the following can apply to a thickness C of a plate 360, 350 in the plate stack: 20 µm ≤ C ≤ 500 µm, such as 150 µm ≤ C ≤ 500 µm, or 250 µm ≤ C ≤ 500 µm.

According to one exemplary embodiment, the following can apply to a plate distance D between adjacent plates 350, 360 in the plate stack: 1 µm ≤ D ≤ 100 µm, such as 20 µm ≤ D ≤ 100 µm, or 40 µm ≤ D ≤ 100 µm.

According to one embodiment of the disclosure, the following relation applies to an overall height H of the plate stack: 50 µm ≤ H ≤ 1000 µm, such as 300 µm ≤ H ≤ 1000 µm, or 500 µm ≤ H ≤ 1000 µm. Here, the overall height H of the plate stack is understood to be the height of the plate stack that is pierced simultaneously via a drilling mechanism 900. Naturally, the micro-optical unit 305 can have at least a second or at least a further plate stack. It is possible that the second or further plate stack of the micro-optical unit is also created via the described method according to the disclosure. However, it is also possible that the second or further plate stack of the micro-optical unit 305 is created via other methods, for example via a planar process and/or lithographic methods. The second or further plate stack can then be aligned relative to the first plate stack.

A relatively large micro-optical unit 305 can be provided in the event of correspondingly large dimensioning of the micro-optical unit 305, for example in the case of an aperture diameter A with A ≥ 150 µm, a thickness C of the multi-aperture plates 350 with C ≥ 250 µm and a plate distance D between the multi-aperture plates 350 of D ≥ 30 µm. Comparatively large voltages U can be applied to this relatively large micro-optic unit 305 during the operation of a multiple particle beam system, for example U ≥ 250 V, such as U ≥ 300 V and U ≥ 350 V. This can be particularly desirable in the case of multiple particle beam systems which operate with a large plurality of individual particle beams 3 since the field dependence of imaging aberrations, for example an image field curvature or an image field astigmatism, in such systems is particularly large, especially in edge regions of a multiple particle beam arrangement of a large raster.

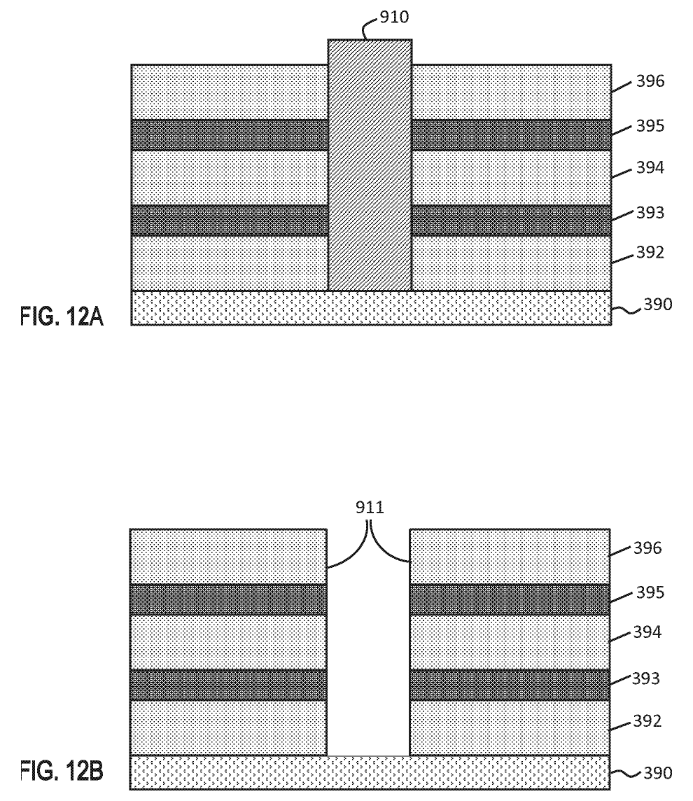

FIGS. 12A-12B schematically shows aspects of a further production method for a micro-optical unit 305. In contrast to the methods already described above, it is no longer the case that an arrangement of different plates on top of one another or of different layers on top of one another is pierced together; instead, a negative mould 910 is provided, around which various layers are initially built up. The negative mould 910 is removed at the end of the process, and so apertures 911 defined by the negative mould 910 are aligned exactly to one another in process-inherent fashion. Thus, a complex alignment issue is also avoided in accordance with this example.

Specifically, the negative mould as such can be provided in a first method step. For example, this may have a Manhattan-like structure that defines the later position of apertures 911. In addition, individual electrodes such as e.g. ring electrodes or lines for supplying voltage to the electrodes can also be provided by this negative mould. This central negative mould, which at least defines the dimensions of subsequent apertures 911, can be configured in various ways. For example, it can be photoresist, silicon dioxide, etched metal (lidar process), coated metal (for deposition purposes), and so on. In FIG. 12A, the negative mould 910 is depicted schematically as a central block. This central block is arranged on a substrate 390. For example, this can be a wafer, e.g. made of silicon.

Various layers can be deposited on the substrate 390 following the provision of this basic structure including the negative mould 910. For example, in the example shown, a first metallic layer 392 can be deposited on the substrate 390, for example via sputtering or via sputtering and electroplating.

Subsequently, a further layer 393 is deposited on the conductive layer 392. In general, this is an insulating layer 393. Either the latter can already be insulating from the outset (for example, deposition of an insulator such as silicon dioxide via sputtering), or the layer can initially be galvanically deposited and then lose its original electrical conductivity through heat treatment and become the insulator. In general, electrolytic processes of isolators are known from the in another context.

The described deposition processes of conductive and non-conductive layers in alternation can be repeated. In the example shown, a metallic layer 394 is then deposited, followed by another insulating layer 395 being deposited; this is then followed by another metallic layer 396, and so on. Then, the negative mould 910 is removed at the end of the method: This is depicted schematically in FIG. 12B. The apertures 911 formed in this process are exactly aligned to one another.

The trick, in which isolators are in general applied galvanically and only become the insulator during heat treatment or during baking, has the feature that, in general, all layers 392 to 396 can be applied galvanically. This is easier in process control, and it is possible to manage without any possible change of machine when applying different layers. The handling of contamination is also less difficult in galvanic processes than in sputtering processes.

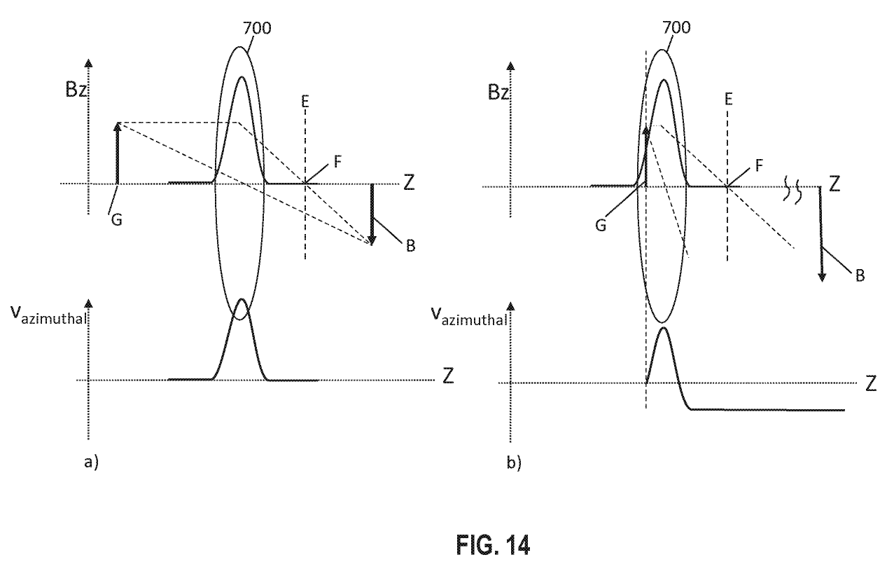

FIGS. 14A-14B schematically illustrate particle-optical imaging through a symmetric and through an asymmetric magnetic lens. The formation of beam tilts is illustrated schematically. Imaging by a symmetric magnetic lens 700 is shown in FIG. 14A. In general, the magnetic lens 700 can be an objective lens, a field lens, a projection lens or any other magnetic lens. In this respect, only the principle is illustrated here. The Y-axis plots the Z-component Bz of the magnetic field caused by the lens 700. An object G to be imaged, represented by an upright arrow, is situated upstream of the magnetic lens 700 in relation to the particle-optical axis Z. What can be relevant here is that the object G to be imaged is located outside the magnetic field of the magnetic lens 700. The particle-optical image B arises downstream of the magnetic lens 700. FIG. 14A plots, by way of example, a particle-optical beam path for a parallel beam or field beam, which is imaged through the focus F in the focal plane E. Furthermore, the central beam is plotted. FIG. 14A thus shows a very general imaging situation via a magnetic lens 700.

Now, the azimuthal velocity component v_{azimuthal} of a particle beam 3, 9 moving parallel to the particle-optical axis Z is plotted below the schematically sketched beam paths through the magnetic lens 700. The azimuthal velocity component v_{azimuthal} is zero before the charged particle beam 3, 9 enters the magnetic lens 700 or its magnetic field B or Bz. The charged particles or particle beams 3, 9 begin to rotate upon entry into the magnetic field B or Bz of the magnetic lens 700, the azimuthal velocity component v_{azimuthal} increases and reaches a maximum value at the centre of the magnetic lens 700. Then the azimuthal velocity component v_{azimuthal} decreases again, and the charged particles or the charged particle beams 3, 9 leave the magnetic lens 700 without an azimuthal velocity component, i.e. v_{azimuthal} = 0.

For comparison purposes, FIG. 14B now illustrates the particle-optical beam path for the case where the magnetic lens 700 is a magnetic immersion lens. Here, the object G to be imaged is therefore situated within the magnetic field B or Bz of the magnetic lens 700. The decisive factor is that the magnetic field B or Bz, which the charged particles or electrons experience and pass through, is not symmetric but is asymmetric: An off-axis electron, which emanates from the object G in a manner parallel to the particle-optical axis, starts without an azimuthal velocity component. It then rotates in the magnetic lens 700 and leaves the magnetic field with an azimuthal velocity component on account of asymmetry. Thus, v_{azimuthal} ≠ 0 applies. This azimuthal velocity component leads to a tilt of the electron beams or, in general, of the charged particle beams. As a consequence, parallel beams for example no longer meet homocentrically in the focal plane E. The situation depicted in FIG. 14B is thus typical, for example, for multi-beam particle microscopes 1 in which the objective lens 102 is a magnetic immersion lens. Thus, beam tilts occur upon incidence on a sample 7.

It is now a fundamental concept of a partial aspect of the disclosure that the above-described beam tilts not only can be caused by an asymmetric magnetic field from the perspective of charged particle beams but also can be compensated: If charged particles or particle beams 3, 9 abruptly enter a magnetic field, then this corresponds in general to an asymmetric passage through the magnetic field of a magnetic lens 700. An appropriate trick thus makes it possible to compensate unwanted beam tilts in the particle-optical beam path or else to set beam tilts in the particle-optical beam path in a targeted manner.

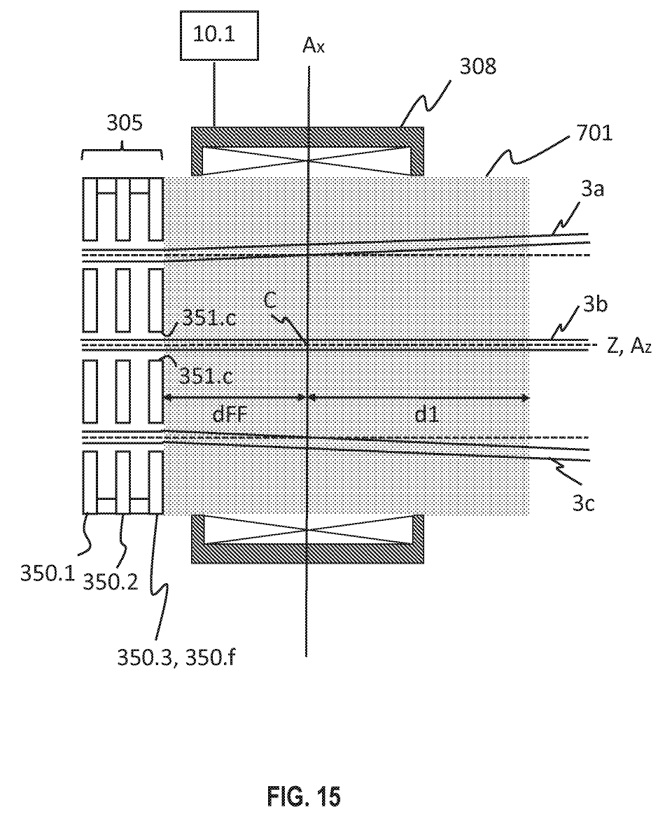

FIG. 15 schematically illustrates an arrangement having a micro-optical unit 305 and having a magnetic lens for the realization of a multi-deflector. The arrangement depicted in FIG. 15 can be integrated into the multi-beam particle microscope 1 shown in FIG. 1, for example; in that case, the magnetic lens corresponds to the magnetic lens 308. This is assumed as an example below.

The micro-optical unit 305 comprises a plurality of successively arranged multi-aperture plates 350.1, 350.2 and 350.3, which are in each case successively passed through by first individual charged particle beams 3. For example, the micro-optical unit 305 can be produced by the method according to the disclosure for producing a micro-optical unit 305 for a multiple particle beam system 1. In relation to the first particle-optical beam path, the micro-optical unit 305 has a final multi-aperture plate 350.f, which corresponds to the multi-aperture plate 350.3 in the example shown. This final multi-aperture plate 350.f is magnetically conductive. The relative permeability µᵣ of the material of the final multi-aperture plate satisfies the relation µᵣ ≥ 1000, for example µᵣ ≥ 10 000 or µᵣ ≥ 15 000. The material of the final multi-aperture plate 350.f can be Permenorm^{®}, for example, or else another material. As regards its central aperture 351.c, the final multi-aperture plate 350.f is arranged centred with respect to the magnetic field lens 308.

In order to provide a setting option or correction option for an azimuthal tilt of the first individual charged particle beams 3a, 3b, 3c, it is now the case that the final multi-aperture plate 350.f of the micro-optical unit 305 is arranged within the magnetic field 701 created by the magnetic field lens 308 during the operation of the multiple particle beam system 1. The magnetic field 701 of the magnetic field lens 308, or a region in which the magnetic field 701 of the magnetic lens 308 is present, is shown schematically in much simplified fashion in FIG. 15 by way of the dotted region.

On account of the magnetic conductivity of the final multi-aperture plate 350.f, the magnetic field 701 of the magnetic lens 308 in FIG. 15 experiences a sharp delimitation in practice, and an abrupt entry of the first individual charged particle beams 3a, 3b and 3c into the magnetic field 701 can be realized. In this case, the azimuthal tilt of the first individual particle beams 3a, 3b, 3c is substantially proportional to the magnetic field strength and dependent on the field height or on the distance of the observed individual charged particle beam 3 from the particle-optical axis Z. Accordingly, the charged particle beam 3a experiences an upward tilt in the example shown, and the charged particle beam 3c experiences a downward tilt while the axial beam 3b on the particle-optical axis Z does not experience any tilt.

The asymmetry of the magnetic field 701 is also shown schematically by a schematic illustration of the principal geometric axis Aₓ of the field lens 308 and by the two distances dFF and d1: The distance dFF between the end of the final multi-aperture plate 350.f and a centre C of the magnetic field lens 308 along the particle-optical axis Z is smaller than the distance d1 from the centre C of the magnetic field lens 308 to the end of the effective range of the magnetic field. In the example shown, dFF ≤ d1 thus applies. In the example shown, dFF is selected in such a way during the operation of the multiple particle microscope 1 that, for example, the following relation applies to the magnetic field 701 or to the magnetic field Bz on the axis Z at the final multi-aperture plate 350.f: 0.1 mT ≤ Bz ≤ 10.0 mT, for example 1.0 mT ≤ Bz ≤ 10.0 mT.

The controller 10 of the multiple particle beam system 1 or a part of the controller 10.1 is configured to control the magnetic field lens 308 and to set its magnetic field strength. Moreover, the controller 10 or a part of the controller 10.1 is also configured in such a way that, via a change in the magnetic field strength of the magnetic field lens 308, an azimuthal tilt of the first individual charged particle beams 3a, 3b, 3c or, in general, of the first individual charged particle beams 3 is set upon incidence on the object 7 and/or when passing through the objective lens 102 of the multiple particle beam system 1.

Furthermore, what holds true in the example shown is that the magnetic field strength of the magnetic field lens 308 is varied by a maximum of +/-50 % of its nominal value for the purpose of setting the azimuthal tilt of the first individual particle beams 3. In this case, the nominal value is defined such that it corresponds to the value of a fully corrected azimuthal beam tilt at the object 7 or at the object surface such as a wafer surface, for example.

FIG. 15 shows a concrete example of a magnetic multi-deflector. This example describes a concrete arrangement of the magnetic multi-deflector in the particle-optical beam path, i.e. in the primary beam path or immediately downstream of the multi-beam generator 305 or of the micro-optical unit 305 in the example shown, by which the plurality of first individual charged particle beams 3 are created at all in the multiple particle beam system. Nevertheless, it is possible in general to provide an arrangement having a micro-optical unit 305 and having a magnetic lens 700 at other positions in the particle-optical beam path, to be precise both in the primary beam path and in the secondary beam path. Thus, the magnetic lens need not be a field lens 308; instead, it can be any desired magnetic lens 700.

Moreover, it is possible in general that the charged particle beams do not enter a magnetic field 701 of a magnetic lens 700 abruptly, but only leave the magnetic field of a magnetic lens 700 abruptly. A fundamental condition for being able to set an azimuthal tilt of individual charged particle beams only lies in the asymmetry of the magnetic field that is passed by the individual charged particle beams. Therefore, rather than arranging a final multi-aperture plate of a micro-optical unit within a magnetic field of a magnetic lens, it is thus also possible to arrange an initial, i.e. first, multi-aperture plate of a micro-optical unit within a magnetic field of a magnetic lens arranged upstream thereof.

The exemplary embodiments described above should not be construed as limiting for the disclosure but instead merely serve for the better understanding of the disclosure. They can be combined with one another in full or in part, provided that no technical contradictions arise as a result.

### LIST OF REFERENCE SIGNS

1 Multiple particle beam system, multi-beam particle microscope
3 Primary particle beams, first individual particle beams
5 Beam spots, incidence locations
7 Object, sample, wafer
9 Secondary particle beams, second individual particle beams
10 Computer system, controller
15 Sample surface, wafer surface
25 Image point of a second individual particle beam
81 Multi-pole electrode
82 Ring electrode
83 Spacer
84 Ring electrode
85 Aperture
86 Spacer
99 Absorbing and conducting layer
101 Object plane
102 Objective lens
103 Field lens
105 Axis
108 Crossover
200 Detector system
205 Projection lens system
206 Projection lens
207 Multi-particle detector
208 Projection lens
209 Projection lens
210 Projection lens
212 Crossover
214 Aperture filter, contrast stop
222 Collective anti-deflection system
300 Beam generating apparatus
301 Particle source
303 Collimation lens system
304 Multi-aperture array, filter plate
305 Micro-optical unit, multi-aperture arrangement, multi-beam particle generator
306 Multi-aperture plate
307 Field lens, aperture plate
308 Field lens
309 Particle beam
310 Multi-aperture plate
321 Intermediate image plane
323 Beam foci
333 Holding region
335 Membrane region
350 Multi-aperture plate
351 Aperture
360 Plate
361 Coarse aperture
362 Conductive region
363 Opening in the conductive region
370 Spacer
380 Frame region
381 Membrane region
382 Cavity
390 Wafer
391 Metallic layer
392 Layer
393 Layer
394 Layer
395 Layer
396 Layer
400 Beam splitter, magnet arrangement
500 Scan deflector
600 Displacement stage or positioning device
700 Magnetic lens
701 Magnetic field
900 Drilling mechanism
901 Base element
902 Manhattan-type electrode
910 Negative mould, photoresist
A Central axis
C Lens centre of the magnetic lens
E Plane
F Focus
G Object
B Image
Bz z-component of the magnetic field
Z axis
M Centre
H Height of the frame section
h Height of the membrane
x Direction
y Direction
z Direction
l Longitudinal axis
dFF Distance between the final multi-aperture plate and the lens centre of the magnetic lens
d1 Distance

What is claimed is:

1. A method, comprising:
stacking a first electrically conductive plate and a second electrically conductive plate to provide a plate stack in which the first and second electrically conductive plates are fixed relative to each other and are electrically insulated from each other; and
piercing the plate stack so that the first electrically conductive plate comprises a first plurality of apertures and the second electrically conductive plate comprises a second plurality of apertures, thereby providing a micro-optical unit comprising the plate stack.

2. The method of claim 1, wherein at least one plate selected from the group consisting of the first electrically conductive plate and the second electrically conductive plate is metallic.

3. The method of claim 2, wherein at least one plate selected from the group consisting of the first electrically conductive plate and the second electrically conductive plate is magnetically conductive and comprises a material having a relative permeability at least 1,000.

4. The method of claim 1, wherein:
the plate stack further comprises a third electrically conductive plate which is fixed relative to the first and second electrically conductive plates and in which the third electrically conductive plate is electrically insulated from the first and second electrically conductive plates; and
the method further comprises piercing the third electrically conductive plate so that the third electrically conductive plate comprises third plurality of apertures.

5. The method of claim 4, wherein the third plate of the micro-optical unit is metallic.

6. The method of claim 1, wherein the plate stack is pierced using at least one method selected from the group consisting of laser drilling, micro-EDM, mechanical high-speed micro-drilling, vibration drilling, and via ultrasonic drilling.

7. The method of claim 1, wherein the plate stack is pierced using a focused ion beam.

8. The method of claim 1, wherein:
the first electrically conductive plate comprises an insulating material as a base material;
the method further comprises before stacking the first electrically conductive plate on the second electrically conductive plate:
creating a plurality of coarse apertures in the first electrically conductive plate; and
metallizing the coarse apertures; and
piercing the first and second electrically conductive plates comprises piercing the metallized coarse apertures to provide the first plurality of apertures in the first electrically conductive plate.

9. The method of claim 1, wherein the first and second pluralities of apertures are simultaneously created, or the first and second pluralities of apertures are successively created.

10. The method of claim 1, wherein each aperture of the first and second pluralities of apertures has a diameter of from 80 micromters to 400 micrometers.

11. The method of claim 1, wherein adjacent apertures of the first and second pluralities of apertures are separated from each other by from 70 micrometers to 400 micrometers.

12. The method of claim 1, wherein the first electrically conductive plate is from 20 micrometers to 500 micrometers thick.

13. The method of claim 1, wherein first electrically conductive plate is a distance of from one micrometer to 100 micrometers from the second electrically conductive plate.

14. The method of claim 1, wherein the plate stack has a height of from 50 micrometers to 1,000 micrometers.

15. The method of claim 1, further comprising, after piercing the plate stack, flushing the plate stack and removing drilling material through flushing holes in the first and second electrically conductive plates, wherein a diameter of the flushing holes is at least 10 times the a diameter the first and second pluralities of apertures.

16. The method of claim 1, further comprising:
before piercing the plate stack:
filling an intermediate space between the first and second electrically conductive plates with a flushing agent; and
cooling the flushing agent to solidify the flushing agent; and
after piercing piercing the plate stack:
heating the flushing agent to liquify the flushing agent; and
removing the flushing agent from the intermediate space.

17. A micro-optical unit, comprising:
a first multi-aperture plate consisting of metal; and
a second multi-aperture plate consisting of metal,
wherein:
the first electrically conductive plate comprises a first plurality of apertures;
the second electrically conductive plate comprises a second plurality of apertures;
a diameter of each aperture of the first and second pluralities of apertures is at least 150 micrometers;
each of the first and second electrically conductive plates is at least 250 micrometers thick; and
a distance between the first and second electrically conductive multi-aperture plates is at least 30 microns.

18. A multiple particle beam system comprising a micro-optical unit according to claim 17.

19. A multiple particle beam system comprising:
a micro-optical unit according to claim 17; and
a controller configured to set a magnetic field strength of a magnetic lens to set an azimuthal tilt of individual particle beams passing through the magnetic lens.

20. A multiple particle beam system, comprising:
a particle source configured to create a charged particle beam;
a multi-beam generator configured so that the charged particle beam passes therethrough during use of the system to form a plurality of first individual charged particle beams that form a first field;
a first particle-optical unit having a first particle-optical beam path, the first particle-optical unit configured to image the first individual particle beams onto an object plane so that the first individual particle beams impinge on an object at incidence locations that form a second field;
an objective lens configured to have the first individual particle beams pass therethrough during use of the system; and
a controller,
wherein:
the multi-beam generator comprises a micro-optical unit comprising a plurality of successively arranged multi-aperture plates which are configured so that during use of the system the successively arranged multi-aperture plates are successively passed by the first individual charged particle beams in each case;
relative to the particle-optical beam path, the plurality of successively arranged multi-aperture plates comprises a final multi-aperture plate which is magnetically conductive and comprises a material having a relative permeability of at least 1,000;
the first particle-optical unit comprises a magnetic field lens;
during use of the system, the final multi-aperture plate of the micro-optical unit is in a magnetic field created by the magnetic field lens;
the controller is configured to control the magnetic field lens and set its magnetic field strength, and
wherein the controller is configured to set a magnetic field strength of a magnetic lens to set an azimuthal tilt of individual particle beams passing through the magnetic lens.
